(19) United States
(12) Patent Application Publication
(10) Pub. No.: US 2015/0299886 A1
(43) Pub. Date: Oct. 22, 2015

(54) METHOD AND APPARATUS FOR PREPARING A SUBSTRATE WITH A SEMI-NOBLE METAL LAYER

(71) Applicant: Lam Research Corporation, Fremont, CA (US)

(72) Inventors: Natalia V. Doubina, Portland, OR (US); Tighe A. Spurlin, Portland, OR (US); Matthew A. Rigsby, Lake Oswego, OR (US); Jonathan D. Reid, Sherwood, OR (US); David Porter, Sherwood, OR (US)

(73) Assignee: Lam Research Corporation, Fremont, CA (US)

(21) Appl. No.: 14/256,671

(22) Filed: Apr. 18, 2014

(51) Int. Cl. C25D 5/34; H01L 21/48; C25D 3/38; C25D 5/10; C25D 5/50

(52) U.S. Cl. CPC C25D 5/34; C25D 5/10; C25D 5/50; C25D 3/38; H01L 21/4814

(57) ABSTRACT

Method and apparatus for preparing a substrate with a semi-noble metal layer are disclosed. The substrate can be pretreated so that a metal oxide surface on the semi-noble metal layer can be reduced to a modified metal surface integrated with the semi-noble metal layer. The substrate can be pretreated using a remote plasma treatment. A copper seed layer can be formed on the semi-noble metal layer using either an acidic or alkaline bath with a plating solution including either at least two copper complexing agents with varying dentacity or a single hexadentate copper complexing agent that is in excess of the copper source. The copper complexing agents can include a hexadentate ligand and a bidentate ligand. In some embodiments, a bulk layer of copper can be subsequently deposited on the copper seed layer using an acidic bath.

### INTRODUCTION

1. Field of the Invention

This disclosure generally relates to preparing a substrate with a semi-noble metal layer. Certain aspects of this disclosure pertain to reducing metal oxide on semi-noble metal layers and plating copper seed with copper complexing agents.

2. Background

Manufacturing of semiconductor devices commonly requires deposition of electrically conductive material on semiconductor wafers. The conductive material, such as copper, is often deposited by electroplating onto a seed layer of copper deposited onto the wafer surface by a physical vapor deposition (PVD) or chemical vapor deposition (CVD) method. Electroplating is a method of choice for depositing metal into the vias and trenches of the processed wafer during damascene and dual damascene processing.

Formation of metal wiring interconnects in integrated circuits (ICs) can be achieved using a damascene or dual damascene process. Typically, trenches or holes are etched into dielectric material, such as silicon dioxide, located on a substrate. The holes or trenches may be lined with one or more adhesion and/or diffusion barrier layers. Then a thin layer of metal may be deposited in the holes or trenches that can act as a seed layer for electroplated metal. Thereafter, the holes or trenches may be filled with electroplated metal. Typically, the seed metal is copper and the holes or trenches are filled with copper.

Because electroplating must occur on a conductive layer, a copper seed layer is first deposited on the diffusion barrier layer with CVD or PVD methods. Chemical vapor deposition (CVD) methods can deposit a conformal copper seed layer with good adhesion, but CVD methods are expensive as compared to PVD processes. Physical vapor deposition (PVD) methods can deposit a copper seed layer with good adhesion, but produces a less conformal film that covers the sidewalls and bottoms of trenches poorly. A thicker PVD seed layer is therefore generally considered necessary to ensure that an electrically conductive layer is provided for subsequent electroplating. The thicker PVD seed layer increases aspect ratios in features and may pinch off the gap opening, making the features harder or impossible to fill with an electroplating process.

To achieve higher performance ICs, many of the features of the ICs are being fabricated with smaller feature sizes and higher densities of components. In some damascene processing, for example, copper seed layers on 2×-nm node features may be as thin as or thinner than 50 Å. In some implementations, metal seed layers on 1×-nm node features may be applied that may or may not include copper. Technical challenges arise with smaller feature sizes in producing metal seed layers and metal interconnects substantially free of voids or defects.

### SUMMARY

This disclosure pertains to methods of preparing a substrate with a semi-noble metal layer for plating copper on the substrate. The method can include providing a substrate with a semi-noble metal layer formed thereon in a processing chamber, exposing the semi-noble metal layer to a reducing treatment under conditions that reduce an oxide of the metal to a metal in the form of a film integrated with the semi-noble metal layer, and depositing a copper seed layer on the semi-noble metal layer using a plating bath with a plating solution. The plating solution includes a copper source and either at least two copper complexing agents having at least two different polydentate ligands or a single hexadentate copper complexing agent, where the single hexadentate copper complexing agent has a concentration at least twice that of the copper source.

In some embodiments, at least one of the polydentate ligands is ethylenediaminetetraacetic acid (EDTA). In some embodiments, at least one of the polydentate ligands is 2,2′-bipyridine. In some embodiments, the semi-noble metal layer includes cobalt. In some embodiments, exposing the semi-noble metal layer to a reducing treatment includes: forming a remote plasma of a reducing gas species in a remote plasma source, where the remote plasma comprises one or more of: radicals, ions, and ultraviolet (UV) radiation from the reducing gas species, and exposing the semi-noble metal layer to the remote plasma. In some embodiments, the plating solution has a pH between about 3.0 and about 13.5. In some embodiments, the method further includes depositing a bulk layer of copper on the copper seed layer using a plating bath different than the plating bath for the deposition of the copper seed layer. The method can further include reflowing the copper seed layer before depositing the bulk layer of copper, where the plating bath for the deposition of the copper seed layer is an alkaline bath and the plating bath for the deposition of the bulk layer of copper is an acidic bath.

This disclosure also pertains to an apparatus for preparing a substrate with a metal seed layer. The apparatus can include a processing chamber, a substrate support for holding the substrate in the processing chamber, and a controller configured to provide instructions for performing the following operations: (a) providing the substrate in the processing chamber, (b) exposing the substrate to a reducing treatment under conditions that reduce an oxide of a metal to a metal in the form of a film integrated with a semi-noble metal layer disposed on the substrate, and (c) depositing a copper seed layer on the semi-noble metal layer using a plating bath with a plating solution. The plating solution includes a copper source and either at least two copper complexing agents having at least two different polydentate ligands or a single hexadentate copper complexing agent, where the single hexadentate copper complexing agent has a concentration at least twice that of the copper source.

In some embodiments, at least one of the polydentate ligands is EDTA. In some embodiments, at least one of the polydentate ligands is 2,2′-bipyridine. In some embodiments, the semi-noble metal layer includes cobalt. In some embodiments, exposing the semi-noble metal layer to a reducing treatment includes forming a remote plasma of a reducing gas species in a remote plasma source, where the remote plasma comprises one or more of: radicals, ions, and ultraviolet (UV) radiation from the reducing gas species, and exposing the semi-noble metal layer to the remote plasma. The reducing gas species can include hydrogen. In some embodiments, the plating solution has a pH between about 3.0 and about 13.5.

### BRIEF DESCRIPTION OF THE DRAWINGS

FIG. 1A shows an example of a cross-sectional schematic of dielectric layers prior to a via etch in a damascene process.

FIG. 1B shows an example of a cross-sectional schematic of the dielectric layers in FIG. 1A after an etch has been performed in the damascene process.

FIG. 1C shows an example of a cross-sectional schematic of the dielectric layers in FIGS. 1A and 1B after the etched regions have been filled with metal in the damascene process.

FIG. 2 shows an exemplary flow diagram illustrating a method of preparing a substrate with a semi-noble metal layer for plating copper on the substrate.

FIG. 3 shows an exemplary flow diagram illustrating a method of preparing a substrate with a semi-noble metal layer for plating copper on the substrate.

FIG. 4A shows an example of a cross-sectional schematic of an oxidized metal layer.

FIG. 4B shows an example of a cross-sectional schematic of a metal layer with a void due to removal of metal oxide.

FIG. 4C shows an example of a cross-sectional schematic of a metal layer with reduced metal oxide forming a reaction product not integrated with the metal layer.

FIG. 4D shows an example of a cross-sectional schematic of a metal layer with reduced metal oxide forming a film integrated with the metal layer.

FIG. 5 shows an example of a cross-sectional schematic diagram of a remote plasma apparatus with a processing chamber.

FIG. 6 shows an example of a cross-sectional schematic view of an embodiment of an electroplating apparatus.

FIG. 7A shows an example of a top view schematic of an electroplating apparatus.

FIG. 7B shows an example of a magnified top view schematic of a remote plasma apparatus with an electroplating apparatus.

FIG. 7C shows an example of a three-dimensional perspective view of a remote plasma apparatus attached to an electroplating apparatus.

FIG. 8 shows an example of an overview for a process flow for a plate on liner sequence.

FIG. 9 shows a comparison between minimal continuous plated copper seed thickness for a plate on cobalt and a plate on ruthenium process.

FIG. 10 shows a comparison between sheet resistance values of plated copper seed at various deposition times on control, wet pre-treated, and dry pre-treated samples.

FIG. 11 shows a comparison between sheet resistance values and minimal continuous plated copper seed thickness on control and dry pre-treated samples.

FIG. 12 shows transmission electron microscopy (TEM) and scanning electron microscopy (SEM) images of bare cobalt as well as copper seed on a cobalt wafer plated with a dual complex alkaline bath.

FIG. 13 shows images of copper fill before and after anneal on copper seed plated on a cobalt wafer with a dual complex alkaline bath.

FIG. 14 shows a graph illustrating cobalt etching in terms of sheet resistance values and thickness in acidic plating conditions and a corresponding x-ray fluorescence (XRF) for the cobalt dissolution rate.

FIG. 15 shows SEM images of copper fill and copper seed plated on a cobalt wafer with a hexadentate complex acidic bath.

FIG. 16 shows images that demonstrate the effect of reflow on copper sheet resistance and roughness.

### DETAILED DESCRIPTION

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

### Introduction

In this disclosure, various terms are used to describe a semiconductor processing work surface, and “wafer” and “substrate” are used interchangeably. The process of depositing, or plating, metal onto a conductive surface via an electrochemical reaction can be referred to generally as electroplating or electrofilling. Bulk electrofilling refers to electroplating a relatively large amount of copper to fill trenches and vias.

Although the present disclosure may be used in a variety of applications, one very useful application is the damascene or dual damascene process commonly used in the manufacture of semiconductor devices. The damascene or dual damascene processes may include metal interconnects, such as copper interconnects.

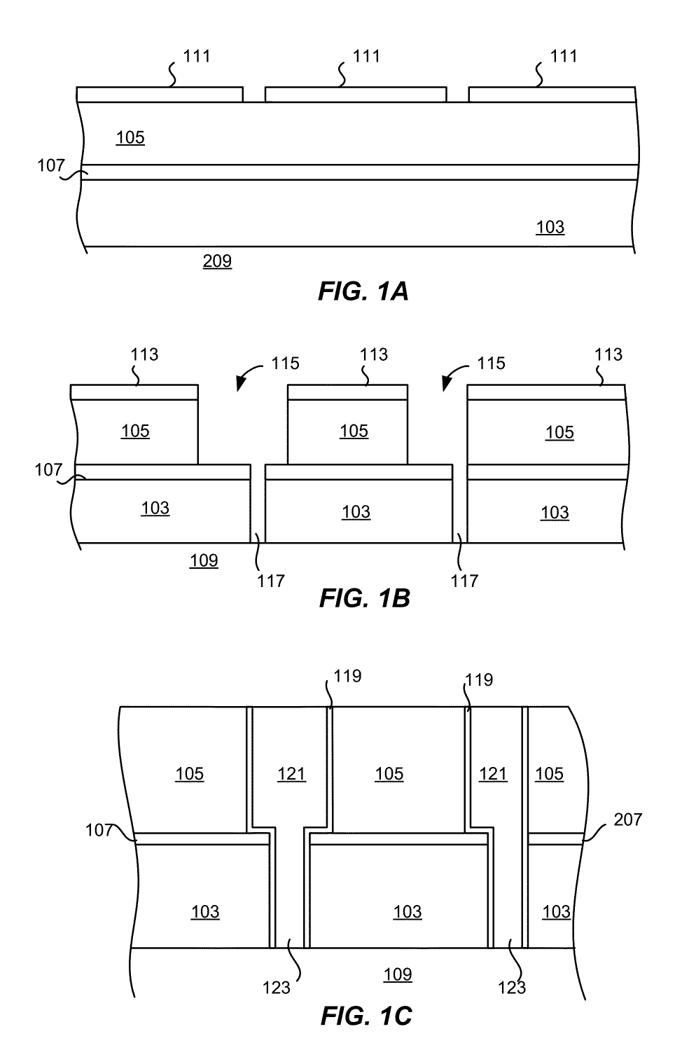

A generalized version of a dual damascene technique may be described with reference to FIGS. 1A-1C, which depicts some of the stages of the dual damascene process.

FIG. 1A shows an example of a cross-sectional schematic of one or more dielectric layers prior to a via etch in a damascene process. In a dual damascene process, first and second layers of dielectric are normally deposited in succession, possibly separated by deposition of an etch stop layer, such as a silicon nitride layer. These layers are depicted in FIG. 1A as a first dielectric layer 103, second dielectric layer 105, and etch stop layer 107. These are formed on an adjacent portion of a substrate 109, which a portion may be an underlying metallization layer or a gate electrode layer (at the device level).

After deposition of the second dielectric layer 105, the process forms a via mask 111 having openings where vias will be subsequently etched. FIG. 1B shows an example of a cross-sectional schematic of the one or more dielectric layers in FIG. 1A after an etch has been performed in the damascene process. Next, vias are partially etched down through the level of etch stop 107. Then via mask 111 is stripped off and replaced with a line mask 113 as depicted in FIG. 1B. A second etch operation is performed to remove sufficient amounts of dielectric to define line paths 115 in second dielectric layer 105. The etch operation also extends via holes 117 through first dielectric layer 103, down to contact the underlying substrate 109 as illustrated in FIG. 1B.

Thereafter, the process forms a thin layer of relatively conductive barrier layer material 119 on the exposed surfaces (including sidewalls) of dielectric layers 103 and 105. FIG. 1C shows an example of a cross-sectional schematic of the dielectric layers in FIGS. 1A and 1B after the etched regions have been coated with a conductive barrier layer material and filled with metal in the damascene process. Conductive barrier layer material 119 may be formed, for example, of tantalum nitride (TaN) or titanium nitride (TiN). A chemical vapor deposition (CVD), an atomic layer deposition (ALD), or a physical vapor deposition (PVD) operation is typically employed to deposit the conductive barrier layer material 119.

On top of the conductive barrier layer material 119, the process then deposits conductive metal 121 (typically, though not necessarily, copper) in the via holes and line paths 117 and 115. Conventionally this deposition is performed in two steps: an initial deposition of a metal seed layer followed by bulk deposition of metal by plating. However, the present disclosure provides a pre-treatment step prior to the bulk deposition step, as described in detail below. The metal seed layer may be deposited by PVD, CVD, electroless plating, or any other suitable deposition technique known in the art. Note that the bulk deposition of copper not only fills line paths 115 but, to ensure complete filling, covers all the exposed regions on top of second dielectric layer 105. The metal 121 may serve as copper interconnects for IC devices. In some embodiments, metals other than copper are used in the seed layer. Examples of such other metals include cobalt, tungsten, and ruthenium.

As the on-chip interconnect wiring dimensions approach and surpass the 45 nanometer (nm) scale, barrier materials are occupying an increasing fraction of the area. This is highly undesirable due to the resulting increase in line resistance resulting from a decrease in total copper volume, as well as possible overhang surrounding the via, which causes the copper electrofill to pinch off and leave void defects in the features. In order to achieve finer features, the multi-layer structure must be simplified. As the scale down of feature sizes continues, there is an increasing demand for a new generation of diffusion barrier materials. Good candidates for future diffusion barriers should have good adhesion to both copper and the dielectric layer, provide a conductive platform for copper plating, and be immiscible with copper.

In addition to using new diffusion barrier materials, the limitations of PVD seed layers should be addressed. The basic requirements for a copper seed layer can include continuous sidewall coverage, adequate opening dimensions at the top of the features after deposition so as to allow bottom-up filling during electroplating, and good adhesion to the barrier layer. The copper seed layer must have low enough resistance to enable subsequent bulk electroplating. Common problems with PVD seed layers can include excessive pinch-off near the feature opening, leading to voids near the center of features during bottom-up filling, and patchy discontinuous seed layers exposing oxidized tantalum barrier onto which electroplating does not take place, such that voids are formed along the sides of the features at the locations of exposed barrier.

One way to address these limitations of PVD copper seed is to use an electroplating process to deposit the seed layer. An electroplating process can deposit a conformal and continuous copper seed layer onto a conductive surface. Electroplating the copper seed layer can include electroplating a semi-noble metal layer. The semi-noble metal layer may be part of a diffusion barrier or serve as the diffusion barrier. Typical diffusion barrier layers such as tantalum and tantalum nitride have relatively high resistivity (about 220 μΩ-cm), and in addition form highly stable oxides onto which electrodeposition of adherent densely nucleated films is difficult or impossible. Ruthenium, cobalt, and other semi-noble metals, which have a resistivity of about 9 μΩ-cm, may be deposited on a TaN layer to provide diffusion barrier/liners of relatively low resistivity. In some instances, the semi-noble metal layer may also be suitable as the diffusion barrier layer. Aspects of the semi-noble metal layer can be further described in U.S. Pat. No. 7,442,267 (attorney docket no. NOVLP350), U.S. Pat. No. 7,964,506 (attorney docket no. NOVLP272), U.S. Pat. No. 7,799,674 (attorney docket no. NOVLP207), U.S. patent application Ser. No. 11/540,937 (attorney docket no. NOVLP175), U.S. patent application Ser. No. 12/775,205 (attorney docket no. NOVLP272X1), and U.S. patent application Ser. No. 13/367,710 (attorney docket no. NOVLP272X2), each of which is incorporated in its entirety by reference.

Even though ruthenium and cobalt are more conductive than TaN, they are still less conductive than a copper seed using a PVD process. For a thin ruthenium film, the sheet resistance is very high, at about 100 to 200 ohm/square. For a thin cobalt film, the sheet resistance is between about 500 and about 900 ohm/square. The sheet resistance of the conductive layer increases as its thickness decreases. When the sheet resistance is high, a voltage drop (termed the terminal effect) exists between the edge of the substrate where electrical contact is made and the center of the substrate. This resistive drop persists during the electroplating process until sufficient plating increases the conductance across the substrate and reduces the voltage drop. The resistive drop results in a larger voltage driving the plating reaction near the edge of the substrate and thus a faster deposition rate at the substrate edge. As a result, the deposited layer has a concave profile with an increased thickness near the edge of the substrate relative to its center. This terminal effect substantially increases the plated thickness near the substrate edge in substrates having seed layers or plated layers with sheet resistances greater than 1 ohm/square, but will result in progressively greater edge thickness as sheet resistance increases further. The impact of terminal effect in generating thickness variation is mostly concentrated in the outer 15 to 30 mm of the substrate diameter, especially in substrates having thin seed layers. Therefore, copper deposition on semi-noble metals such as ruthenium and copper with conventional electroplating processes yields edge thick films due to this high resistance.

When plating on a high resistance surface, the electrolyte should ideally have low conductivity. When the bath conductivity is decreased, the relative voltage drop between the substrate center and substrate edge compared to the overall voltage drop through the plating cell becomes small. The thickness distribution is improved because the voltage driving the reaction at the substrate edge is not much larger relative to that at the substrate center. A low conductivity (high resistivity) electrolyte has a resistivity higher than about 200 ohm-cm, higher than about 1000 ohm-cm in some embodiments, which is significantly higher than the conventional electroplating baths resistivity of about 2 ohm-cm to about 20 ohm-cm.

Metal seed layers, including the semi-noble metal layers, can readily react with oxygen or water vapor in the air and oxidize from a pure metal into a mixed film of a metal oxide and a buried pure metal. While the oxidation under ambient conditions may be limited to a thin surface layer of some metals, that thin layer may represent a significant fraction or perhaps the entire thickness of thin seed layers used in current technology nodes. The relatively thin layers may be necessitated by the technology node, such as the 4× nm node, the 3× nm node, the 2× nm node, and the 1× nm node, and less than 10 nm. The height to width aspect ratio of vias and trenches in technology nodes necessitating relatively thin metal layers can be about 5:1 or greater. In such technology nodes, the thickness of the metal seed layer can be less than about 100 Å on average as a result. In some implementations, the thickness of the metal seed layer can be less than about 50 Å on average.

Through the general chemical reactions shown in Equation 1 and Equation 2 below, metals used for seed layers and semi-noble metal layers are converted to metal oxides (Mox), though the exact reaction mechanisms between the metal surfaces (M) and ambient oxygen or water vapor can vary depending on the properties and the oxidation state.

2M₍ₛ₎+O_{2(g)}2MOx₍ₛ₎ Equation 1

2M₍ₛ₎+H₂O_{(g)}→M₂Ox+H_{2(g)} Equation 2

For example, copper seed deposited on substrates is known to rapidly form copper oxide upon exposure to the air. A copper oxide film can form a layer that is approximately 20 Å and upwards to 50 Å thick on top of underlying copper metal. Moreover, cobalt layers deposited on substrates are known to rapidly form cobalt oxide. A cobalt oxide film can form a layer on top of the underlying cobalt metal that can covert upwards of 70%, 80%, 90%, and 98% of the cobalt metal to cobalt oxide. As metal seed layers become thinner and thinner, the formation of metal oxides from oxidation in ambient conditions can pose significant technical challenges.

Conversion of pure metal seed to metal oxide can lead to several problems. This is true not only in current copper damascene processing, but also for electrodeposition processes that use different conductive metals, such as ruthenium, cobalt, silver, aluminum, and alloys of these metals. First, an oxidized surface is difficult to plate on. Due to different interactions that electroplating bath additives can have on metal oxide and pure metal, non-uniform plating may result. As a result of the differences in conductivity between a metal oxide and a pure metal, non-uniform plating may further result. Second, voids may form in the metal seed that may make portions of the metal seed unavailable to support plating. The voids may form as a result of dissolution of metal oxide during exposure to corrosive plating solutions. The voids also may form on the surface due to non-uniform plating. Additionally, plating bulk metal on top of an oxidized surface can lead to adhesion or delamination problems, which can further lead to voids following subsequent processing steps, such as chemical mechanical planarization (CMP). Voids that result from etching, non-uniform plating, delamination, or other means may make the metal seed layer discontinuous, and unavailable to support plating. In fact, because modern damascene metal seed layers are relatively thin, such as about 50 Å or thinner, even a little oxidation may consume an entire layer thickness. Third, metal oxide formation may impede post-electrodeposition steps, such as capping, where the metal oxide may limit adhesion for capping layers.

The aforementioned issues may also occur for plating metal seed layers on semi-noble metal layers. Substrates with a semi-noble metal layer, such as a cobalt layer, may have significant portions of the semi-noble metal layer converted to oxide. Plating a metal seed layer, such as a copper seed layer, on the semi-noble metal layer can lead to void formation, pitting, non-uniform plating, and adhesion/delamination problems.

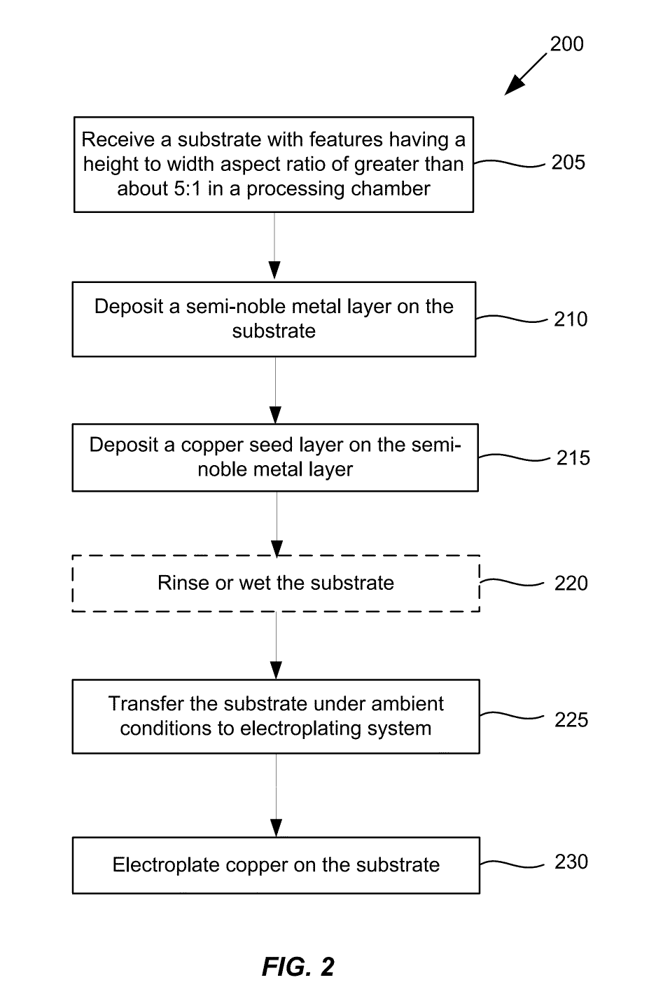

FIG. 2 shows an exemplary flow diagram illustrating a method of preparing a substrate with a semi-noble metal layer fbr plating copper on the substrate. The process 200 may begin at step 205, where a process chamber or deposition chamber receives a substrate such as a semiconductor substrate. The substrate may include feature having sidewalls and bottoms. The features may be a dielectric material with trenches and vias etched therein for depositing of liner/barrier layer and copper interconnect. The features may also include some liner/barrier layer material. For example a layer of titanium (Ti), tantalum (Ta), tantalum nitride (TaN), tantalum nitride silicon (TaNSi), tungsten (W), titanium nitride (TiN), or titanium nitride silicon (TiNSi) may be deposited first. The features are commonly trenches and vias for forming copper interconnects in a damascene process. In some embodiments, the features may have depths of about 15 nm to 100 nm and may have openings with a dimension of about 10 nm to about 30 nm before the semi-noble metal layer and the copper seed layer are deposited. In some embodiments, the features have a height to width aspect ratio of greater than about 5:1, such as greater than about 10:1.

The process 200 may continue at step 210, where a semi-noble metal layer is deposited on the substrate. The semi-noble metal may be ruthenium, palladium, rhodium, iridium, osmium, cobalt, or nickel. In certain embodiments, the semi-noble metal is cobalt. Typically, the semi-noble metal layer is deposited using an ALD or CVD process. Both ALD and CVD-type deposition techniques are considered to result in smooth and conformal layers within the features, thereby increasing the process window to obtain void-free fill in the subsequent electroplating step. The availability of appropriate precursors which do not have a deleterious impact on either the dielectric or copper for these semi-noble metals allows for the deposition of these layers using either of these processes. An ALD process deposits a very thin layer of material using alternating doses of precursor material that first saturates the surface and then forms the thin layer deposit. A CVD process involves providing one or more gaseous reactants to the chamber (at the same time if there are multiple reactants) that react to deposit a film on the surface of the substrate, with or without plasma. The CVD process can deposit more material than the ALD process in the same amount of time. Although only ALD and CVD methods are commonly used to deposit a semi-noble metal layer, other deposition processes may be used.

In a semiconductor manufacturing environment, the substrate undergoes processing on many different semiconductor processing tools or apparatuses. Usually, the semi-noble metal layer and the copper seed layer are deposited using a processing tool different from that of the bulk layer electroplating. In some instances, the copper seed layer may be deposited using the same tool as the bulk layer electroplating, if an electroplating process is used for the copper seed layer.

The process 200 continues at step 215, where a copper seed layer is deposited on the semi-noble metal layer. Generally, the copper seed layer may be deposited using a number of methods including PVD, CVD, electroplating, and electroless plating. The seed layer may have an average thickness of about 15 Å to about 100 Å or larger. In some embodiments, the seed layer can have a thickness between about 40 Å and about 80 Å. While electroplating may be used to deposit the copper seed layer on a semi-noble metal layer, a commonly accepted method for mass manufacturing is PVD. As discussed, PVD seed layers may be non-uniform and spotty, leaving some semi-noble metal layers exposed. Because the resistivity of the semi-noble metal layer is much lower than those of conventional barrier materials, such as tantalum, along with the fact that their oxides can be reduced, allows for the possibility of subsequent bulk layer electroplating.

At optional step 220, the substrate may be rinsed and dried. For example, the metal seed layer may be rinsed with de-ionized water. The rinsing step may be limited to a time, for example, of between about 1 and 10 seconds, but may take a longer or shorter time. Subsequently, the substrate may be dried, which can be between about 20 and 40 seconds, though the drying step may take a longer or shorter time.

At step 225, the substrate is transferred to the electroplating system or bath. In some instances, the substrate may be transferred to a plating bath having a different plating solution than the plating solution for depositing the copper seed layer. During the transfer, the copper seed layer may be exposed to ambient conditions such that the copper seed layer may rapidly oxidize. In some embodiments, the duration of this exposure may be anywhere between about 1 minute and about 4 hours, between about 15 minutes and about 1 hour, or more. At step 230, a bulk layer of copper may be electroplated on the substrate. The substrate with the copper seed layer over the semi-noble metal layer can be, for example, immersed in an electroplating bath containing positive ions of copper and associated anions in an acid solution. At the plating bath, a bulk layer of copper is electroplated onto the substrate to fill the features. A conventional electroplating chemistry and waveform may be used. The bulk layer electroplating process is able to completely fill the features without any voids even if the copper seed is discontinuous because the exposed semi-noble metal layer can be electroplated to produce a strongly adherent copper seed/semi-noble interface. In certain embodiments, the electroplating chemistry and current or potential waveform are modified slightly to compensate for the slightly higher resistivity and sheet resistance from having some exposed semi-noble metal surface. For example, the slightly higher resistivity may increase a terminal effect during bulk layer electroplating and with certain modifications, as described below, may be used to counter the terminal effect. In some embodiments, step 230 of FIG. 2 can involve a series of processes that is described in U.S. Pat. No. 6,793,796, filed Feb. 27, 2001 (attorney docket no. NOVLP073), the entirety of which is hereby incorporated by reference. The reference describes at least four phases of the electrofilling process and discloses controlled current density methods for each phase for optimal filling of relatively small embedded features.

Various steps may expose the copper seed layer and the semi-noble metal layer to oxidation. The oxidation may occur on the semi-noble metal layer, forming semi-noble metal oxides prior to depositing the copper seed layer. The oxidation may also occur between the deposition of the copper seed layer and electroplating the bulk layer. With various steps that may expose the copper seed layer and the semi-noble metal layer to oxidation, a technique for reducing the negative effects of the metal oxide surfaces is needed. However, some of the current techniques may have drawbacks. Typically, the use of hydrogen-based plasmas may reduce thick metal oxides, but such techniques add substantial costs and utilize substantially high temperatures (e.g., at least over 200° C.) that can badly damage a thin metal seed layer resulting in high void counts within features. A thermal forming gas anneal to reduce thick metal oxides uses a forming gas (e.g., mixture of hydrogen and nitrogen gas) at temperatures higher than 150° C., which can cause metal seed to agglomerate and also lead to increased voiding. The use of acids or other chemical reagents to dissolve or etch the oxide may be used as an alternative or in addition to the presently disclosed methods, though it may result in metal dissolution and barrier exposure especially in cases where the metal film stack is extremely thin (e.g., less than 1.5 nm).

The present disclosure provides methods for treating a substrate with a semi-noble metal layer and depositing a copper seed layer thereon. The method of treating the substrate with the semi-noble metal layer can include exposing semi-noble metal oxide surfaces to a reducing treatment. The semi-noble metal oxide is reduced to a semi-noble metal in the form of a film integrated with the semi-noble metal layer. In addition, the method of depositing the copper seed layer on the semi-noble metal layer includes the use of a plating solution that contains a copper source and either at least two copper complexing agents (multidentate ligands) or a single hexadentate copper complexing agent (that may be at least twice as concentrated as the copper source). The plating solution can be used in the range of about pH 3 to about pH 13.5. Typically, the optimal nucleation may occur at either low pH (pH 3) or high pH (pH 13). Further treatment of the copper seed layer can include reflowing the copper to reduce voids and gaps. Reflowing the copper can mobilize the copper and redistribute atoms in the copper seed layer to improve seed coverage and/or smoothness, thereby forming a more uniform and continuous seed layer.

Method of Preparing a Substrate with a Semi-Noble Metal Layer for Plating Copper on the Substrate

A method of preparing a substrate with a semi-noble metal layer for plating copper on the substrate can be disclosed. The substrate can have features with a semi-noble metal layer formed thereon, and a copper seed layer formed on the semi-noble metal layer. The semi-noble metal layer may be treated by a reducing treatment to reduce metal oxides in the semi-noble metal layer. The copper seed layer may be formed on the semi-noble metal layer using either an acidic or alkaline plating bath, where a plating solution includes either at least two copper complexing multidentate agents or a single copper complexing hexadentate agent, where the copper complexing hexadentate agent has a concentration at least twice that of a copper source. An extra copper complexing agent can serve to suppress plating voltage and remove undesired copper oxide to achieve improved nucleation of copper on the semi-noble metal layer.

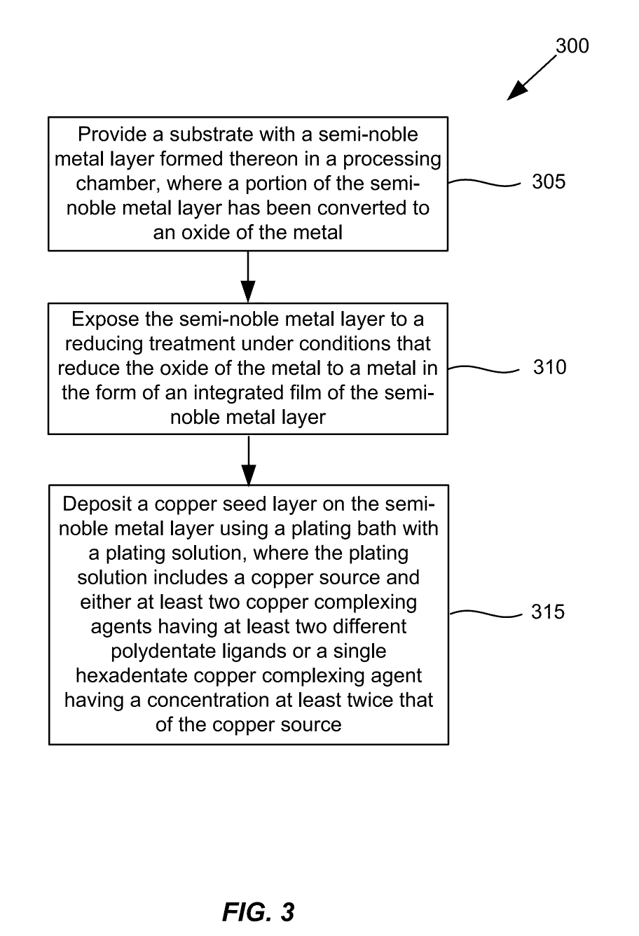

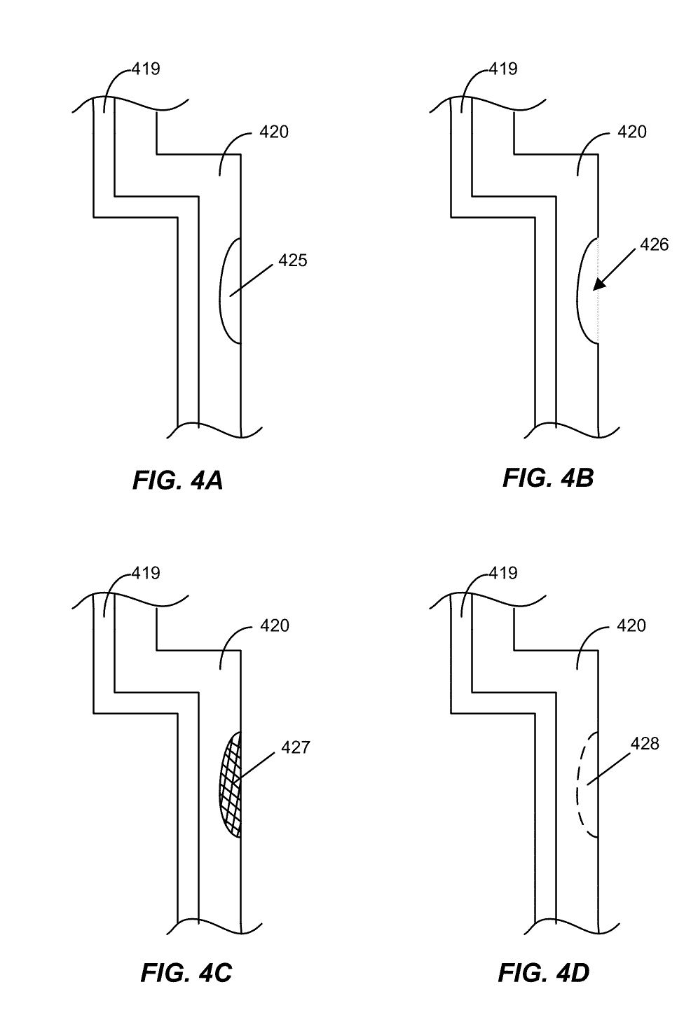

FIG. 3 shows an exemplary flow diagram illustrating a method of preparing a substrate with a semi-noble metal layer for plating copper on the substrate. The operations in a process 300 may be performed in different orders and/or with different, fewer, or additional operations. The process 300 may be described with reference to some examples as illustrated in FIGS. 4A-4D.

The process 300 can begin with step 305 where a substrate with a semi-noble metal layer formed thereon is provided in a processing chamber. The substrate may include features, which may be similarly described with reference to step 205 in FIG. 2. The features may include trenches or vias having a height to width aspect ratio of greater than about 3:1, or greater than about 5:1, or greater than about 10:1. The semi-noble metal layer may be deposited on the substrate as generally described with reference to step 210 in FIG. 2.

A portion of the semi-noble metal layer may have been converted to an oxide of the semi-noble metal. In some embodiments, the semi-noble metal layer includes cobalt. After deposition, cobalt may be oxidized as soon as the vacuum is broken. The as-provided cobalt layer may be covered by a thin layer of cobalt oxide, which can lead to further problems of void formation, pitting, non-uniform plating within the features, and adhesion/delamination issues caused by poor interface quality. In some embodiments, a substantial portion of the cobalt layer can be converted to cobalt oxide, such as more than about 70%, more than about 80%, more than about 90%, or more than about 95% of elemental composition of the cobalt layer being converted to cobalt oxide.

Step 305 can occur in a deposition apparatus such as a PVD apparatus. In some embodiments, the process 300 can continue where the substrate is transferred to a chamber or apparatus having a substantially reduced pressure or vacuum environment. In some embodiments, the chamber or apparatus can include a reducing gas species. In some embodiments, the reducing gas species can include hydrogen (H₂), ammonia (NH₃), carbon monoxide (CO), diborane (B₂H₆), sulfite compounds, carbon and/or hydrocarbons, phosphites, and/or hydrazine (N₂H₄). During the transfer, the substrate may be exposed to ambient conditions that can cause the surface of the semi-noble metal layer to oxidize. Thus, at least a portion of the semi-noble metal layer may be converted to an oxidized metal.

The process 300 can continue at step 310, where the semi-noble metal layer is exposed to a reducing treatment under conditions that reduce the oxide of the metal to a metal in the form of a film integrated with the semi-noble metal layer. In some embodiments, the reducing treatment may be a wet treatment, where the wet treatment can include contacting the oxide of the metal with a solution containing a reducing agent. The reducing agent can include a boron-containing compound, such as a borane or borohydride, a nitrogen-containing compound, such as a hydrazine, and a phosphorus-containing compound, such as a hypophosphite. The solution can include additives like an accelerator or additives that increase the wetting potential of the surface of the copper seed layer or that increase the stability of the reducing agent. A wet treatment for reducing oxides of a metal to a metal in the form of a film integrated with a metal seed layer can be described in U.S. patent application Ser. No. 13/741,141 (attorney docket no. LAMRP018), filed Jan. 14, 2013.

In the alternative or in addition to the wet treatment, the reducing treatment may be a dry treatment. Exposing the semi-noble metal layer to a dry treatment may include forming a remote plasma of a reducing gas species in a remote plasma source, where the remote plasma includes one or more of: radicals, ions, and ultraviolet (UV) radiation from the reducing gas species. The semi-noble metal layer may be exposed to the remote plasma to reduce the oxide of the metal to a metal in the form of a film integrated with the semi-noble metal layer.

The remote plasma may include radicals of the reducing gas species, such as, for example, H*, NH₂*, or N₂H₃. The radicals of the reducing gas species react with the metal oxide surface to generate a pure metallic surface. As demonstrated below, Equation 3 shows an example of reducing gas species such as hydrogen gas being broken down into hydrogen radicals. Equation 4 shows the hydrogen radicals reacting with the metal oxide surface to convert the metal oxide to metal. For hydrogen gas molecules that are not broken down or hydrogen radicals that recombine to form hydrogen gas molecules, the hydrogen gas molecules can still serve as a reducing agent for converting the metal oxide to metal, as shown in Equation 5.

H₂→2H* Equation 3

(x)2H*+MOx→M+(x)H₂O Equation 4

xH₂+MOx→M+xH₂O Equation 5

The radicals of the reducing gas species, ions from the reducing gas species, ultraviolet (UV) radiation from the reducing gas species, or the reducing gas species itself react with the metal oxide under conditions that convert the metal oxide to metal in the form of a film integrated with the metal seed layer. Characteristics of the film integrated with the metal seed layer are discussed in further detail with respect to FIGS. 4A-4D.

FIGS. 4A-4D show examples of cross-sectional schematics of a metal layer deposited on a conductive barrier layer. However, it will be understood by a person of ordinary skill in the art that the metal layer may be part of the conductive barrier layer.

FIG. 4A shows an example of a cross-sectional schematic of an oxidized metal layer deposited over a conductive barrier layer 419. The metal layer may include a semi-noble metal layer upon which a copper seed layer may be formed subsequently thereon. As discussed earlier herein, the metal layer 420 may be oxidized upon exposure to oxygen or water vapor in ambient conditions, which can convert metal to a metal oxide 425 in a portion of the metal layer 420.

FIG. 4B shows an example of a cross-sectional schematic of a metal layer with a void due to removal of metal oxide. As discussed earlier herein, some solutions treat the metal oxide 425 by removal of the metal oxide 425, resulting in voids 426. For example, the metal oxide 425 can be removed by oxide etching or oxide dissolution by an acid or other chemical. Because the thickness of the void 426 can be substantially large relative to the thinness of the metal layer 420, the effect of the void 426 on subsequent plating can be significant.

FIG. 4C shows an example of a cross-sectional schematic of a metal layer with reduced metal oxide forming a reaction product not integrated with the metal layer. As discussed earlier herein, some treatments reduce the metal oxide 425 under conditions that agglomerate metal with the metal layer 420. In some embodiments, reducing techniques generate metal particles 427, such as copper powder, that can agglomerate with the metal layer 420. The metal particles 427 do not form an integrated film with the metal layer 420. Instead, the metal particles 427 are not continuous, conformal, and/or adherent to the metal layer 420.

FIG. 4D shows an example of a cross-sectional schematic of a metal layer with reduced metal oxide forming a film integrated with the metal layer. In some embodiments, radicals from a reducing gas species, ions from the reducing gas species, UV radiation from the reducing gas species, or the reducing gas species itself can reduce the metal oxide 425. When process conditions for the reducing gas atmosphere are appropriately adjusted, the metal oxide 425 in FIG. 4A may convert to a film 427 integrated with the metal layer 420. The film 427 is not a powder. In contrast to the example in FIG. 4C, the film 427 can have several properties that integrate it with the metal layer 420. For example, the film 427 can be substantially continuous and conformal over the contours metal layer 420. Moreover, the film 427 can be substantially adherent to the metal layer 420, such that the film 427 does not easily delaminate from the metal layer 420.

Returning to FIG. 3, the reducing treatment may include forming a remote plasma of a reducing gas species in a remote plasma source, where the remote plasma includes one or more of radicals, ions, and UV radiation from the reducing gas species, and exposing the semi-noble metal layer to the remote plasma. The remote plasma may generate and include ions and other charged species of the reducing gas species. The ions and charged species of the reducing gas species may move to the surface of the substrate to react or otherwise contact the semi-noble metal layer. The ions or charged species may freely drift toward the surface of the substrate or be accelerated toward the surface of the substrate when an oppositely charged bias is provided on a substrate support. The ions or charged species may react with the metal oxide to reduce the metal oxide. In some implementations, the ions or charged species in the remote plasma can include, for example, H⁺, NH₂⁺, NH₃⁺, and H⁻. Ions or charged species may be advantageous for reducing oxide on metal layers depending on a thickness and nature of the oxide layers, which can form on cobalt, ruthenium, palladium, rhodium, iridium, osmium, nickel, gold, silver, aluminum, tungsten, and alloys thereof. For example, the ions or charged species may be beneficial for treatment of a metal layer containing cobalt.

The remote plasma may also generate and include UV radiation from the reducing gas species. Excitation of the reducing gas molecules from the remote plasma may cause emission of photons. The emitted photons may lead to one of several effects. First, the emitted photons in the UV spectrum may heat the surface of the substrate to activate the metal oxide surface so that radicals, ions, and other charged species can more readily react with the metal oxide surface. Second, reducing gas species may absorb the emitted photons and generate radicals of the reducing gas species. The generated radicals may react with the metal oxide surface to reduce the metal oxide. Third, the emitted photon may have sufficient energy to cause reduction of the metal oxide itself.

The energy of the remote plasma may be increased to generate higher energy species, including higher energy ions. Higher energy ions may be produced in high density plasma (HDP) processing systems and/or sputtering systems. Also, when the remote plasma generates UV radiation as a result of excitation of the reducing gas species, the generated UV radiation can have a wavelength between about 100 nm and about 700 nm. For example, the generated UV radiation can include short wavelength UV light, such as between about 120 nm and about 200 nm, and long wavelength UV light, such as between about 200 nm and about 700 nm. In addition, the remote plasma may include neutrals and/or generate recombined molecules of the reducing gas species. When the oxide of the metal is exposed to the remote plasma, the exposure reduces the oxide of the metal and reflows the metal in the metal layer. In some implementations, reflow of the metal and the reduction of the metal oxide may occur concurrently. In some implementations, the remote plasma can include radicals, ions, and UV radiation from the reducing gas species, or some combination thereof. A showerhead between the remote plasma source and the processing chamber can have a thickness, a number of holes, and an average diameter of holes configured to permit radicals, ions, and UV radiation flow or otherwise travel through the showerhead toward the substrate. The radicals, ions, and UV radiation may enter the processing chamber and reduce metal oxide in the semi-noble metal layer. High energy ions may penetrate further from the surface of the substrate to provide a reducing chemistry throughout more of the semi-noble metal layer. UV radiation may activate the metal oxide surface to improve the thermodynamics of the reduction process, or directly reduce the metal oxide itself. The UV radiation may also be absorbed by the reducing gas species and give rise to radicals that can reduce metal oxide. Furthermore, neutral molecules of the reducing gas species may further react and reduce metal oxide in the semi-noble metal layer.

In some embodiments, the metal in the semi-noble metal layer may be excited and mobilized upon exposure. The metal may be reflowed to reduce gaps and voids in the semi-noble metal layer, which can reduce the surface roughness of the semi-noble metal layer. How much the metal is reflowed can depend on the temperature of the substrate, the chamber pressure, the reducing gas species, and the intensity of the UV radiation, for example. As the metal is reflowed and redistributed on the underlying layer, a more uniform and continuous semi-noble metal layer can be formed.

The process conditions for converting the metal oxide to metal in the form of a film integrated with the metal layer can vary depending on the choice of metal and/or on the choice of the reducing gas species. In some embodiments, the reducing gas species can include at least one of H₂, NH₃, CO, carbon and/or hydrocarbons, B₂H₆, sulfite compounds, phosphites, and N₂H₄. In addition, the reducing gas species can be combined with mixing gas species, such as relatively inert gas species. Examples of relatively inert gas species can include nitrogen (N₂), helium (He), neon (Ne), krypton (Kr), xenon (Xe), radon (Rn), and argon (Ar). The flow rate of the reducing gas species can vary depending on the size of the substrate for processing. For example, the flow rate of the reducing gas species can be between about 10 standard cubic centimeter per minute (sccm) and about 100,000 sccm for processing a single 450 mm substrate. Other substrate sizes can also apply. For example, the flow rate of the reducing gas species can be between about 500 sccm and about 30,000 sccm for processing a single 300 mm substrate.

Processing conditions such as temperature and pressure in the reducing chamber can also be controlled to permit conversion of the metal oxide to metal in the form of a film integrated with the metal layer. In some embodiments, the temperature of the reducing chamber can be relatively high to permit the dissociation of reducing gas species into radicals. For example, the reducing chamber can be anywhere between about 10° C. and about 500° C., such as between about 50° C. and about 250° C. Higher temperatures may be used to speed up metal oxide reduction reactions and shorten the duration of exposure to the reducing gas atmosphere. In some embodiments, the reducing chamber can have a relatively low pressure to substantially remove any oxygen from the reducing gas atmosphere, as minimizing the presence of oxygen in the atmosphere can reduce the effects of reoxidation. For example, the reducing chamber can be pumped down to a vacuum environment or a reduced pressure of between about 0.1 Torr and about 50 Torr. The increased temperature and/or the reduced temperature can also increase reflow of metal atoms in the metal layer to create a more uniform and continuous metal layer.

Although the reducing chamber can have a relatively high temperature to permit the dissociation of reducing gas species into radicals, the temperature of the substrate itself may be separately controlled to avoid or reduce damage to the metal layer. Depending on the type of metal in the metal layer, the metal can begin to agglomerate above a threshold temperature. The effects of agglomeration is more pronounced in relatively thin seed layers, especially in seed layers having a thickness less than about 100 Å. Agglomeration includes any coalescing or beading of a continuous or semi-continuous metal layer into beads, bumps, islands, or other masses to form a discontinuous metal layer. This can cause the metal layer to peel away from the surface upon which it is disposed and can lead to increased voiding during plating. For example, the temperature at which agglomeration begins to occur in copper is greater than about 100° C. For cobalt, an agglomeration temperature is higher than for copper. For example, a temperature at which agglomeration and fill detrimental effects can be seen occurs at temperatures greater than about 350° C. Different agglomeration temperatures may be appropriate for different metals.

To control the temperature of the substrate and avoid or reduce the effects of agglomeration, a cooling system such as an actively cooled pedestal and/or gas flow cooling apparatus in the reducing chamber can be used to keep the local area of the substrate at temperatures below the agglomeration temperature. In some embodiments, the substrate may be supported upon and directly in contact with the pedestal. In some embodiments, a gap may exist between the pedestal and the substrate. Heat transfer can occur via conduction, convection, radiation, or combinations thereof.

In some implementations, an actively cooled pedestal provides a heat transfer element with resistive heating elements, cooling channels, or other heat sources or sinks embedded within the pedestal. For example, the pedestal can include cooling elements that permit a fluid such as water to circulate within the pedestal and actively cool the pedestal. In some embodiments, the cooling elements can be located outside the pedestal. In some embodiments, the cooling fluid can include a low-boiling fluid, such as glycols. Embodiments that include such cooling elements can be described in U.S. Pat. No. 7,327,947 (attorney docket no. NOVLP127X1), issued Feb. 5, 2007; U.S. Pat. No. 7,941,039 (attorney docket no. NOVLP127X3), issued Jan. 5, 2011; U.S. patent application Ser. No. 11/751,574 (attorney docket no. NOVLP127X2), filed May 21, 2007; U.S. patent application Ser. No. 13/370,579 (attorney docket no. NOVLP127C1), filed Feb. 10, 2012; and U.S. Pat. No. 7,137,465 (attorney docket no. NOVLP127), issued Mar. 20, 2012, each of which are incorporated herein by reference in its entirety and for all purposes. Temperature in the pedestal can be actively controlled using a feedback loop.

In some implementations, a gap can exist between the pedestal and the substrate, and a conductive media such as gas can be introduced between the pedestal and the substrate to cool the substrate. In some embodiments, the conductive media can include helium. In some embodiments, the pedestal can be convex or concave to promote uniform cooling across the substrate. Examples of pedestal profiles can be described in U.S. patent application Ser. No. 11/129,266 (attorney docket no. NOVLP361), filed May 12, 2005; U.S. patent application Ser. No. 11/546,179 (attorney docket no. NOVLP197), filed Oct. 10, 2006; and U.S. patent application Ser. No. 12/749,170 (attorney docket no. NOVLP361D1), filed Mar. 29, 2010, each of which is incorporated herein by reference in its entirety and for all purposes.

Different configurations can be utilized to efficiently cool and to maintain a substantially uniform temperature across the substrate. Some implementations of an active cooling system include a pedestal circulating water within the pedestal coupled with a uniform gas flow across the substrate. Other implementations include a pedestal resistively heated coupled with a uniform gas flow across the substrate. Other configurations and/or additions may also be provided with the active cooling system. For example, a removable ceramic cover can be inserted between the pedestal and the substrate to promote substantially uniform temperature across the substrate, as described in U.S. patent application Ser. No. 13/076,010 (attorney docket no. NOVLP400), filed Apr. 13, 2011, which is incorporated herein by reference in its entirety and for all purposes. In some embodiments, gas flow can be controlled with minimum contact supports to rapidly and uniformly cool the substrate, as described in U.S. Pat. No. 7,033,771 (attorney docket no. NOVLP297), issued Oct. 11, 2011, which is incorporated herein by reference in its entirety and for all purposes. In some embodiments, the heat transfer coefficient of the conductive media can be adjusted by varying the partial pressure of the conductive media as described in U.S. Pat. No. 7,277,277 (attorney docket no. NOVLP232), issued Oct. 12, 2012, which is incorporated herein by reference in its entirety and for all purposes. Other configurations for a localized cooling system for maintaining a relatively low substrate temperature can be utilized as is known in the art.

The temperature of the substrate can be maintained at a temperature below the agglomeration temperature of the metal using any of the cooling systems discussed earlier herein or as is known in the art. In some embodiments, the substrate can be maintained at a temperature between about −10° C. and about 150° C. In copper seed layers, for example, the substrate can be maintained at a temperature between about 75° C. and about 100° C. In cobalt seed layers, the substrate can be maintained at a temperature greater than about 100° C.

The duration of exposure to the reducing gas atmosphere can vary depending on the other process parameters. For example, the duration of exposure to the remote plasma can be shortened by increasing remote plasma power, temperature of the reducing chamber, etc. In certain embodiments, the duration of the exposure to reduce the metal oxide surfaces to pure metal in an integrated film with the metal layer can be between about 1 second and about 60 minutes. For example, for pretreatment of copper seed layers, the duration of the exposure can between about 10 seconds and about 300 seconds.

While most reducing treatments may require that the substrate be rinsed and dried prior to plating in order to clean the substrate surface, the substrate as exposed to a remote plasma need not be rinsed and dried prior to plating. Thus, reducing metal oxide surfaces using a remote plasma can avoid the additional step of rinsing and drying the substrate before plating, which can further reduce the effects of reoxidation.

In some implementations, the metal in the metal layer may be reflowed as a result of exposure to one or more of increased temperature, reduced pressure, UV radiation from a UV source, UV radiation from the remote plasma, and radicals, ions, and other charged species from the remote plasma. Such exposure can lead to atoms in the metal layer to enter a more excited state and become more mobile. The atoms can move around on an underlying layer to reduce voids/gaps. As a result, a more uniform and continuous metal seed layer can be created. In some implementations, the reflow and the reduction treatment can occur simultaneously.

In some implementations, the remote plasma may not only reduce metal oxide to metal for more uniform plating, the remote plasma may also increase the conductivity of the semi-noble metal layer by removing organic impurities left behind from the as-deposited semi-noble metal layer. For example, the remote plasma may remove organic impurities left behind from CVD-deposited cobalt layers.

After pretreating the substrate with a remote plasma to reduce semi-noble metal oxides to semi-noble metal, the substrate can be exposed to a cooling gas in some implementations. The cooling gas can include at least one of argon, helium, and nitrogen. Exposing the substrate to the cooling gas can cool the substrate to a temperature below about 30° C. Thus, the cooling gas can be delivered at a temperature below ambient conditions to cool the substrate.

In some embodiments, the substrate may be transferred under ambient conditions or under a blanket of inert gas to an electroplating system, electroless plating system, metal deposition system, or other pretreating apparatus. After exposing at least the oxide of the metal to a reducing treatment, the substrate may be transferred to an electroplating system including a plating bath containing a plating solution. Though metal oxides in the metal layer have been substantially reduced by exposing the metal oxide surfaces to a reducing gas atmosphere, transferring may present an additional challenge of reoxidation from exposure to the ambient environment. In some embodiments, exposure to ambient conditions may be minimized using techniques such as shortening the duration of transfer or controlling the atmosphere during transfer. Additionally or alternatively, the transfer is conducted in a controlled environment that is less oxidizing than ambient conditions. To control the atmosphere during transfer, for example, the atmosphere may be substantially devoid of oxygen. The environment may be substantially inert and/or be low pressure or vacuum. In some embodiments, the substrate may be transferred under a blanket of inert gas. As discussed below, the transfer may occur from a remote plasma apparatus to an electroplating system, where the remote plasma apparatus is integrated or otherwise connected to the electroplating system.

At step 315, a copper seed layer is deposited on the semi-noble metal layer using a plating bath with a plating solution, where the plating solution includes a copper source and at least two copper complexing agents, the at least two copper complexing agents including at least two different polydentate ligands. In some embodiments, the plating solution includes a single hexadentate copper complexing agent, wherein the single copper complexing agent has a concentration at least twice that of the copper source.

In some embodiments, the copper seed layer may be deposited with an electroplating process using forward and reverse current pulses. For example, in some embodiments employing 300 mm substrates, in an electroplating process a forward current of about 0.5 amps to 1.25 amps may be applied for about 2 seconds to 5 seconds and a reverse current of about 0.1 amps to 2 amps may be applied for about 50 milliseconds to 600 milliseconds. This sequence may be repeated for about 15 seconds to 60 seconds to electroplate the copper seed layer. In some embodiments, the reverse current may be about 0.1 amps to 0.5 amps for a period of about 100 milliseconds to 600 milliseconds. In some other embodiments, a reverse current of about 1 amp to 2 amps may be applied for about 50 milliseconds to 200 milliseconds.

For example, in some embodiments, in an electroplating process a forward current of about 0.75 amps may be applied for about 3 seconds and a reverse current of about 0.4 amps may be applied for about 150 milliseconds. This sequence may be repeated for about 30 seconds to electroplate the copper seed layer. In some other embodiments, in an electroplating process a reverse current may have a larger magnitude than a forward current. For example, a forward current may be about 0.75 amps and may be applied for about 3 seconds and a reverse current may be about 1.5 amps and may be applied for about 100 milliseconds. This sequence may be repeated for about 30 seconds to electroplate the copper seed layer. Additionally, over the duration of the seed deposition process, the number of coulombs passed in the forward current operations exceeds the number of coulombs passed in the reverse current operations.

In some embodiments, the reverse current operations may remove a portion of the copper seed layer in the peripheral regions of the substrate. That is, a portion of the copper seed layer on the surface of the substrate near the edges of the substrate may be removed when the reverse current is applied. Removing the copper seed layer from the peripheral regions of the substrate may aid in countering the terminal effect during the bulk layer copper electroplating operation. In some embodiments, the last operation in the seed layer electroplating process may include a reverse current pulse.

Deposition thickness may vary between the edge and the center of a substrate when electroplating onto a thin film having a high sheet resistance. Ways to reduce the terminal effect can include different configurations of a plating apparatus. These hardware configurations may be used during the seed layer deposition. Yet another way to decrease this effect is to increase the resistivity of the electrolyte so that the relative change in potential between the substrate center and the substrate edge compared to the overall potential drop through the plating cell becomes small. A special electrolyte, therefore, may be used for plating a seed layer of copper onto a semi-noble metal layer formed on a substrate.

Copper plating electrolytes may include a copper source, which may include Cu(OH)₂. The copper in Cu(OH)₂ may be complexed out by a copper complexing agent. Copper plating electrolytes typically use a copper salt, such as Cu(OH)₂, as an ion source. The anions from the salt used can contribute significantly to the conductivity of the solution. One factor affecting the conductivity of the electrolyte is the mobility of the ions. A copper salt having larger ions in solution would be less mobile, and the solution less conductive. However, the hydroxide ion would have a higher mobility than the larger anions. Suitable salts can include, for example, copper citrate (Cu₃(C₆H₅O₇)₂), copper pyrophosphate (Cu₂P₂O₇), and copper oxalate (CuC₂O₄). In general, molecular ions which are highly hydrated or which have more than 6 non-hydrogen atoms are sufficiently large to reduce the mobility of the ion in solution and are considered sufficiently large to reduce the conductivity of the electrolyte compared to the effect of equivalent concentration of small highly mobile ions such as hydrogen. The electrolyte composition may be tailored to mitigate corrosion of the semi-noble metal layer on the substrate. Depending on the semi-noble metal, this may involve adjusting the pH to a level that does not significantly attack the metal, including a compound that promotes reduction at the metal, and/or excluding agents that attack the metal (such as excluding molecular oxygen and agents that complex ions of the metal).

In certain embodiments, the copper seed electrolyte has a resistivity of greater than about 200 ohm-cm, or conductivity less than about 5 milliSiemens. In various further embodiments, the resistivity is about 200 ohm-cm to about 5000 ohm-cm, about 400 ohm-cm to about 4000 ohm-cm, or about 1000 ohm-cm to about 2000 ohm-cm. A person of ordinary skill in the art will readily be able to choose a resistivity that allows a thickness distribution within a uniformity requirement on a given semi-noble metal layer resistance using particular hardware configurations. A common uniformity requirement of thickness difference between the edge and the center of the substrate is a range of about +/−10%, or less than about +/−5%.

The electrolyte can also include either at least two copper complexing agents with different dentacity, or a single hexadentate copper complexing agent that has a concentration at least twice in excess of a copper source. Complexing agents are additives that bind the copper cation in solution, thereby increasing the degree of polarization, or the potential required to reduce the cupric ion to metal. It is believed that the copper nucleation and growth mode is sensitive to the oxidation state of the semi-noble metal layer surface. Because the semi-noble metal layer may be deposited in a different process with different semiconductor processing tools than the copper seed layer, the surface may be covered with an air-formed oxide film as described earlier. Failure to remove the oxide film may result in Volmer-Weber (island) growth on the surface. In order to achieve continuous copper nucleation in the electroplating bath, the oxide film may be treated using a reducing treatment as described earlier with respect to step 310.

Each of the copper complexing agents can include polydentate ligands. One suitable complexing agent is ethylenediaminetetraacetic acid (EDTA). The copper in Cu(OH)₂ is can be complexed out by EDTA. EDTA is a hexadentate (six-toothed) ligand, i.e., it has 6 lone pairs of electrons all of which can form coordinate bonds with the same metal ion. EDTA forms extremely stable complexes with divalent metal cations using all of its complexing sites that give rise to a cage-like structure in which the cation is effectively surrounded by and isolated from solvent molecules. A consequence of the stronger complexing ability of EDTA is that a larger cathodic potential is required for the reduction of cupric ions to copper metal (range of about 0.7 V to 1.7 V). Such extreme negative copper reduction potential may also reduce the any oxide film on the semi-noble metal layer, resulting in continuous nucleation on the surface. If the electrolyte contains no complexing agent, copper will deposit at much lower cathodic potentials (about 0.6 V). The oxide film will not be removed and poor nucleation may result with the attending effect of rapid growth on initially formed nuclei. Therefore, the plating reaction in accordance with some embodiments deposits copper at a potential that is about 0.2 to 1 V more cathodic than would occur in a copper-plating electrolyte with no complexing agent.

In addition, the electrolyte can include a second copper complexing agent, where the second copper complexing agent includes a polydentate ligand. For example, a first copper complexing agent can include a hexadentate ligand, such as EDTA, and the second copper complexing agent can include a bidentate ligand, such as a bipyridine. An example of a suitable bipyridine can include 2, 2′-bipyridine. Other complexing agents having bidentate ligands include phenanthroline, ethylenediamine, oxalate, and acetylacetonate. In addition, any of the aforementioned complexing agents can include other polydentate ligands. Complexing agents with tridentate ligands can include terpyridine and citrate. A complexing agent with a tetradentate ligand can include triethylenetetramine, a complexing agent with a pentadentate ligand can include ethylenediaminetriacetic acid, and a complexing agent with a hexadentate ligand can include EDTA.

Other suitable complexing agents can include pyrophosphate, triethanolamine, dimercaptosuccinic acid, nitrilotriacetate, dimercaprol, defuroxamine mesylate, and a combination of the aforementioned complexing agents. Incorporating any of these complexing agents may also increase the cathodic potential and remove oxide on the semi-noble metal layer.

In some embodiments, incorporation of the second copper complexing agent like 2,2′-bipyridine can increase the cathodic potential by at least about 200 mV. The increased cathodic potential can lead to better nucleation of copper on the semi-noble metal layer. Using the electrolyte as described, the copper plating reaction can occur at a cathodic potential of about 1.0V to about 2.5V. Plating potential may be affected by the substrate. For example, plating on a thin cobalt substrate, such as a substrate with a 1.5 nm layer of cobalt, may result in a cathodic potential of about 2.5V.

A hexadentate ligand like EDTA can form stable complexes with metal cations like copper. The hexadentate ligand can have a strong complexing ability to complex with copper ions and suppress the formation of undesired copper oxide species that may precipitate. A bidentate ligand like 2,2′-bipyridine can also serve as a complexing agent to remove or otherwise complex with copper ions. However, while the bidentate ligand like 2,2′-bipyridine may not be as strong as a complexing agent like EDTA, it may serve to remove uncomplexed copper oxide that may precipitate out. This can result in increased plating bath stability. Moreover, use of a bidentate ligand 2,2′-bipyridine does not dissolve a semi-noble metal like cobalt, which may result from extra EDTA due to its strong complexing ability.

The second copper complexing agent like 2,2′-bipyridine can also serve as a brightening agent, improving the quality of the copper seed deposition and providing for a smooth surface. In some embodiments, the electrolyte may have a pH of about 3.0 to about 13.5. While the solution may be used at a wide range of pH levels, typical plating solutions are adjusted to either acidic or alkaline values of the spectrum (e.g., pH 3.0 and pH 13.5) In some instances, the pH may be less than 7.5 if the cathodic potential is high enough to suppress the dissolution of the semi-noble metal. In the instances when the pH is in the acidic range, the entry potential needs to be high enough to suppress the dissolution of the semi-noble metal. Additionally, if using an acidic bath an open-circuit potential step (OCP) may be beneficial in dissolving the oxide. In acidic conditions, the use of an induction step at or near zero applied current can be beneficial. Under these open-circuit conditions, surface cobalt oxide may dissolve rapidly, exposing the bare cobalt metal, which may dissolve slowly by comparison. By examining the evolution of the open-circuit potential, the appropriate duration of the induction step can be determined. If the induction step is too short, surface oxides may not be completely removed, whereas if the induction step is too long, a galvanic displacement reaction will become problematic. This type of open-circuit induction can be beneficial for (a) removal of surface oxides to plate on bare metal and (b) for thinning down a thicker cobalt layer to a more desirable thickness.

In some embodiments, the electrolyte can also include a wetting agent. In some implementations, the plating solution may adapt a DirectSeed™ chemistry that includes Cu(OH)₂ with EDTA in relatively equimolar ratios and a pH of about 3.0. The adapted DirectSeed™ chemistry may include 2,2′-bipyridine in relatively equimolar ratios along with a wetting agent, such as polyethylene glycol (PEG) or another suppressor. Moreover, the adapted DirectSeed™ chemistry may have a pH greater than about 7.5.

In some implementations, the first and second complexing agents may be mixed in relatively equal concentrations. For example, EDTA and 2,2′-bipyridine can be in relatively equal concentrations of about 5 mM each even though EDTA may displace 2,2′-bipyridine as a stronger complexing agent. Nonetheless, 2,2′-bipyridine may serve a brightening agent and to re-complex undesired copper oxide species that precipitated out. In other implementations, the complexing agent may be a single species such as EDTA or N-(2-hydroxyethyl) ethylenediaminetriacetic acid (HEDTA) with a concentration in excess of the copper source which is typically copper hydroxide. In one example, a modified DirectSeed™ chemistry can have about 5 mM of 2,2′-bipyridine, 5 mM of EDTA, and PEG, where a pH of the plating solution can be between about 3.0 and 13.5. In another example, a modified DirectSeed™ chemistry can have about 5 mM of Cu(OH)₂, 10 mM of EDTA, and PEG, where a pH of the plating solution can be between about 3.0 and 13.5.

In some embodiments, the electrolyte that includes a copper source and the at least two copper complexing agents, (i) can be substantially free of chemical species that are corrosive to the semi-noble metal layer and (ii) can have a pH of about 3.0 to about 13.5. The electrolyte being free of chemical species that are corrosive to the semi-noble metal layer and the electrolyte having basic pH (such as a pH above 7) helps to avoid corrosion of the semi-noble metal layer being plated on, which may be very thin or if the electrolyte is in the acidic pH range, an entry potential which is prevents cobalt dissolution is required. In certain embodiments, the semi-noble metal layer may be cobalt, which can be susceptible to corrosion by an electrolyte.

For example, when no voltage is applied, cobalt becomes cobalt ion (Co²⁺) at a pH less than about 8. Thus, if the copper seed layer is plated on cobalt in a conventional acidic plating bath without applied potential entry, the cobalt is likely to dissolve during the initial stages of plating. Non-uniform dissolution of cobalt can result in voids, which can lead to non-uniform plating.

Chemical species that are corrosive to the semi-noble metal layer may include a number of different compounds and elements. In some embodiments, such compounds and elements may be excluded from the electrolyte. For example, halides such iodine and chlorine, which are corrosive to the semi-noble metal layer, may be excluded from the electrolyte. In further embodiments, oxygen can be excluded from the electrolyte. Molecular oxygen can be highly corrosive to certain semi-noble metal layer. Oxygen can be substantially removed from and/or prevented from being dissolved in the electrolyte using a degassing device or a vacuum degassing device, by flowing gasses (e.g., nitrogen or hydrogen) through the electrolyte, or by blanketing the electrolyte with an inert gas (e.g., nitrogen). Examples of commercially available degassing devices include the Liquid-Cel™ from Membrana of Charlotte, N.C. and the pHasor™ from Entegris of Chaska, Minn. Decreasing the dissolved oxygen levels in the electrolyte to less than about 1 ppm has also been shown to result in improved copper nucleation on semi-noble metal layers.

The electrolyte may also include a corrosion inhibiting agent. Some corrosion inhibiting agents produce a reducing potential at the semi-noble metal layer surface. Examples of corrosion inhibiting agents include formaldehyde, glyoxylic acid, hydrazine, dimethylamine borane, and sodium hypophosphite.

In certain embodiments, the terminal effect is mitigated or eliminated by adjusting the potential or current applied to edge of the substrate (that in turn affects the current density across the substrate) such that current efficiency varies across the face of the substrate. This may be accomplished by adjusting the overall potential or current applied to the substrate such that the current density approaches or surpasses the copper limiting current density at or near the edge of the substrate. In some embodiments, the current density surpasses the limiting current density at a point between the edge of the substrate and the center of the substrate. As explained herein, electrical contact is made at the substrate edges, and for a high sheet resistance semi-noble metal layer (which may be partially covered with a partial copper seed layer), the voltage drops from the edges of the substrate to the center. Applying a potential to the edge of the substrate causes copper to electrodeposit onto the substrate at different radially varying current densities.

The total current density of an electroplating process is the amperage of the electroplating current divided by the surface area of the semiconductor wafer. As noted above, the current density may vary across the surface of the substrate. Generally, the higher the current density, the faster the copper electrodeposition rate. Due to the higher potential at the edges of the substrate, the current density at the edges of the substrate is higher than the current density at the center of the substrate, yielding a concave copper thickness profile.

In typical copper plating configurations, the reduction of copper (II) ions to metallic copper is responsible for all or nearly all of current density at the substrate surface. Thus, the contribution of copper reduction to the total current density roughly tracks the current density, but this is true only up to a certain point, beyond which the copper current density cannot increase even if the potential or total current applied to the substrate is increased significantly. This maximum contribution of the copper reduction reaction to current density is termed the copper limiting current density. When the cell's total current density exceeds the copper limiting current density, current density in excess of the copper limiting current is manifest as parasitic electrochemical reactions, such as the electrolysis of water.

Current efficiency is the percentage of total current which is actually used for the copper deposition at the cathode (i.e., the current not including current used for in parasitic electrochemical reactions). When the copper current density for copper deposition exceeds the copper limiting current density, the current efficiency decreases because current that is not being used for copper deposition is consumed by the parasitic electrochemical reactions. When operating at total currents where the copper's limiting current density is exceeded at the edge of the substrate but not the center, the terminal effect is compensated. As more total current is applied in this regime, the copper deposition rate increases in the center of the substrate relative to the edge of the substrate. Some of this additional current can be used for copper deposition in the center of the substrate but not the edge. Thus, by increasing the potential or current applied at the edges of the substrate, the current efficiency profile of the copper deposition process may be varied. In some embodiments, the current efficiency at the edge of the substrate is about 20 to 30% and the current efficiency at the center of the substrate is about 50 to 60% or even higher. This mitigates the terminal effect, resulting in a more even copper seed layer deposition rate across the substrate surface, and ultimately can result in an about 30% to 40% improvement in the thickness uniformity of the copper seed layer deposited across the face of the substrate.

In summary, the electrolytic seed deposition process may be conducted in a regime where the local current density is at or above the limiting current density of copper reduction at the edge of the substrate. This produces a current efficiency profile that varies radially over the face of the substrate. The copper current efficiency drops off rapidly for current densities in excess of the copper limiting current density. The combination of electrolyte composition and total current to the substrate can be tailored to operate in this regime and provide a more uniform copper deposition profile in situations where the terminal effect, if unmitigated, would produce a highly non-uniform deposition profile.

A similar reduction in the terminal effect can also be accomplished by reducing the mass transfer of copper ions, without necessarily reaching the limiting current density, near the edge of the substrate to the point that the electroplating process is mass transfer limited in that region, as described in U.S. Pat. Nos. 6,110,346, 6,162,344, and 6,074,544, which are incorporated herein by reference in their entirety and for all purposes.

In certain embodiments, a copper alloy seed layer is deposited on the semi-noble metal layer using an electroplating process. The copper alloy may be, for example, an alloy of copper with chromium, iron, cobalt, nickel, zinc, ruthenium, rhodium, palladium, silver, indium, tin, tellurium, platinum, gold, or lead. The copper alloy may include one or more of these alloying elements. In various embodiments, the copper alloy seed layer includes about 0.1 to 5 weight percent of an alloying element or elements. The alloying element may provide some protection against damage resulting from electromigration.

The copper seed layer or the copper alloy seed layer may be treated using a reducing treatment to reduce copper oxides to copper. Prior to depositing a bulk layer of copper on the seed layer, copper oxides may form on the surface that can lead to voids and non-uniform plating. In some embodiments, oxidation may result from exposure to the tool environment during transfer of the substrate from a plating bath for the seed layer to a plating bath for the bulk electrofill. The reducing treatment may include a wet treatment or a dry treatment, as described earlier with respect to reducing metal oxides in a semi-noble metal layer.

In some embodiments, the copper seed layer may be reflowed prior to bulk electroplating. Reflowing the copper in the copper seed layer may mobilize atoms to reduce voids and other discontinuities in the copper seed layer. The copper seed layer may be reflowed using a remote plasma. In some instances, the copper seed layer may be reflowed using a heat treatment, such as an anneal operation.

After depositing the copper seed layer or copper alloy seed layer on the semi-noble metal layer, a bulk layer of copper can be deposited on the seed layer. Bulk electrofilling can refer to electroplating a relatively large amount of copper to fill features, including trenches and vias. In some embodiments, the plating bath used for the bulk deposition of copper may be different than the plating bath used for the seed deposition of copper. For example, the plating bath used for the bulk deposition of copper may be acidic whereas the plating bath used for the seed deposition of copper may be alkaline.

The electrolyte used to deposit the bulk layer of copper may be different from the electrolyte used to deposit the seed layer of copper. When depositing the copper seed, the electrolyte may include, for example, complexed copper. When depositing the bulk layer of copper, the electrolyte may include, for example, low acid VMS with organic additives. The current density for copper seed deposition may be about 1 mA/cm² while the current density for bulk electrofill may be about 10 mA/cm². Examples of electroplating methods for depositing bulk copper fill can be described in U.S. Pat. No. 6,946,065 (attorney docket no. NOVLP071D1) and also in U.S. Pat. No. 7,799,674 (attorney docket no. NOVLP207), both of which are incorporated herein by reference in their entirety and for all purposes.

Depositing the bulk layer of copper may be achieved by electroplating, which can be difficult if the seed layer is very thin and discontinuous. However, reducing metal oxides using a reducing treatment on the semi-noble metal layer and/or the copper seed layer can minimize the discontinuities and voids in the seed layer for more uniform plating. The reducing treatment may also increase the conductivity of the semi-noble metal layer by removing organic impurities left behind from the as-deposited semi-noble metal layer. Moreover, using a plating solution including at least two complexing agents with two different polydentate ligands can further improve the smoothness and nucleation of the seed layer while also reducing the terminal effect. Where the semi-noble metal dissolves in acidic mediums, the plating solution may be an alkaline solution to avoid in-situ dissolution of the semi-noble metal.

The plating solution can typically be composed of copper sulfate, sulfuric acid, chloride ions and organic additives. Sulfuric acid is added to the electrolyte to enhance conductivity of the plating solution. This allows electroplating at reduced applied voltages and improves uniformity of voltage applied to surfaces at varying distances from an anode. Uniform voltages lead to uniform deposition rates. Conversely, when anode and wafer are equidistant at all points, lower concentrations of acid can be used to uniformly increase resistance between the wafer and the anode. This large uniform increase in resistance can diminish the terminal effect of resistive seed layers. Therefore, it is preferred to use electrolytes with low or medium concentrations of sulfuric acid while plating on thin seed layers. Another method to increase the resistance of the electrolyte may be to use salts that form large anions in solution, discussed above.

By way of an example, a substrate may be provided with a cobalt film formed thereon. The cobalt film may have a thickness less than about 50 Å. However, the as-deposited cobalt film may have a significant portion converted to cobalt oxide, and the cobalt film can have a relatively high sheet resistance. Hence, pretreatment of the cobalt film can reduce cobalt oxide to cobalt metal in a form integrated with the rest of the cobalt film, where the pretreatment can include exposure to a remote plasma. Furthermore, a more negative cathodic potential can be achieved using a plating solution with a copper complexing agent EDTA and another copper complexing agent 2,2′-bipyridine for plating the copper seed layer on the highly resistive cobalt film. The resulting copper seed layer demonstrates improved nucleation and smoothness in the copper seed layer than a plating solution without the copper complexing agent 2,2′-bipyridine. The plating solution may also be set at a pH level that is either acidic or alkaline to achieve improved nucleation and cobalt oxide removal.

### Remote Plasma Apparatus

A remote plasma apparatus for preparing a substrate with a semi-noble metal layer is disclosed. The remote plasma apparatus includes a processing chamber, a substrate support for holding the substrate in the processing chamber, a remote plasma source over the substrate support, a showerhead between the remote plasma source and the substrate support, one or more movable members in the processing chamber, and a controller. The one or more movable members may be configured to move the substrate to positions between the showerhead and the substrate support. The controller may be configured to perform one or more operations, including providing the substrate in the processing chamber, moving the substrate towards the substrate support, forming a remote plasma of a reducing gas species in the remote plasma source where the remote plasma includes radicals of the reducing gas species, exposing the metal seed layer of the substrate to the radicals of the reducing gas species, and exposing the substrate to an inert gas. The remote plasma may also include ions of the reducing gas species, UV radiation from the reducing gas species, and the reducing gas species itself.

The remote plasma apparatus can be configured to perform a plurality of operations that is not limited to preparing a substrate with a remote plasma. The remote plasma apparatus can be configured to transfer (such as load/unload) a substrate efficiently to and from an electroplating apparatus, electroless plating apparatus, or other metal deposition apparatus. The remote plasma apparatus can be configured to efficiently control the temperature of the substrate by positioning the substrate using movable members and/or the using substrate support. The remote plasma apparatus can be configured to efficiently control the temperature of the substrate by controlling the temperature of the substrate support and the temperature of the showerhead. The remote plasma apparatus can be configured to tune the rate of reduction reaction and the uniformity of the reduction reaction by positioning the substrate support relative to the showerhead. The remote plasma apparatus can be configured to control the environmental conditions surrounding the substrate by controlling the gases and flow rates of the gases delivered into the processing chamber. Such operations can improve the processing of the substrate while also integrating additional operations into a single standalone apparatus. Thus, a single apparatus can be used for treating and cooling the substrate, rather than using two separate modules. Furthermore, by configuring the remote plasma apparatus to be able to perform some of the operations described above, the remote plasma apparatus can reduce potential oxidation of one or both of the semi-noble metal layer and copper seed layer before, during, and after processing of the substrate.

In some implementations, the remote plasma apparatus can include a processing chamber, a substrate support for holding a substrate having a metal seed layer in the processing chamber, a remote plasma source over the substrate support, a showerhead between the remote plasma source and the substrate support, and a controller. The controller may be configured to perform one or more operations, including providing the substrate with the metal seed layer in the processing chamber, where a portion of the metal seed layer has been converted to oxide of the metal, forming a remote plasma in the remote plasma source, where the remote plasma includes one or more of: radicals, ions, and UV radiation from the reducing gas species, and exposing the metal seed layer of the substrate to the remote plasma, where exposure reduces the oxide of the metal and reflows the metal in the metal seed layer.

In some implementations, the remote plasma apparatus can further include a UV source. The UV source can include UV broadband lamps such as mercury lamps, UV excimer lamps, UV excimer lasers, and other appropriate UV sources. Aspects of the UV source can be described in U.S. patent application Ser. No. 13/777,499 (attorney docket no. LAMRP027), filed Mar. 6, 2013, which is incorporated herein by reference in its entirety and for all purposes. In some implementations, the reducing gas species can be exposed to UV radiation from the UV source to form radicals and other charged species of the reducing gas species, which can react with a metal oxide surface of a metal layer to reduce metal oxide.

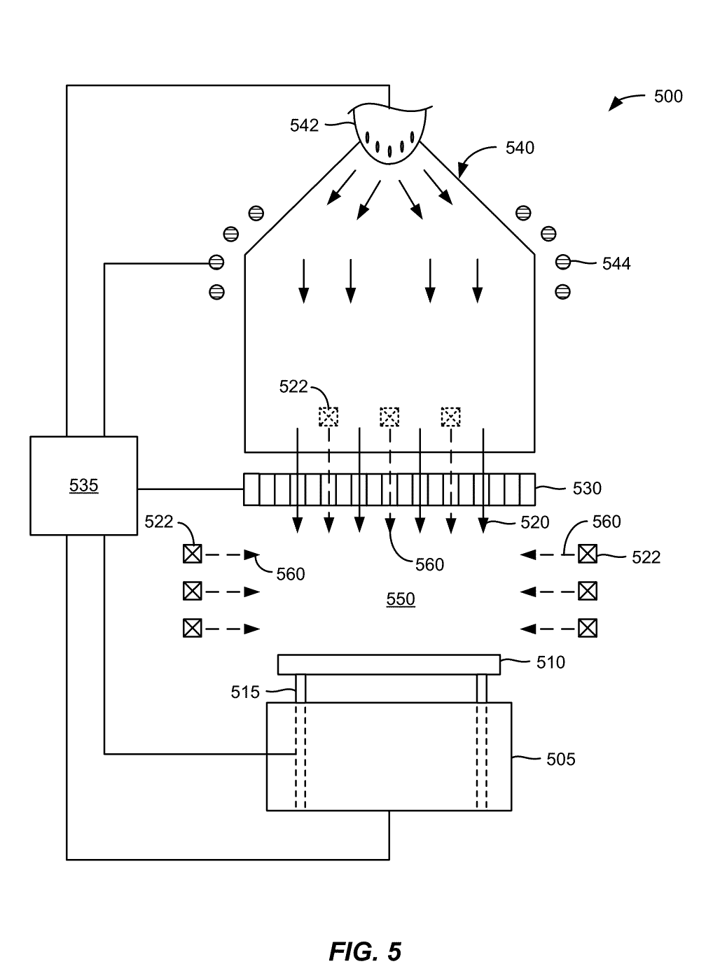

FIG. 5 shows an example of a cross-sectional schematic diagram of a remote plasma apparatus with a processing chamber. The remote plasma apparatus 500 includes a processing chamber 550, which includes a substrate support 505 such as a pedestal, for supporting a substrate 510. The remote plasma apparatus 500 also includes a remote plasma source 540 over the substrate 510, and a showerhead 530 between the substrate 510 and the remote plasma source 540. A reducing gas species 520 can flow from the remote plasma source 540 towards the substrate 510 through the showerhead 530. A remote plasma may be generated in the remote plasma source 540 to produce radicals of the reducing gas species 520. The remote plasma may also produce ions and other charged species of the reducing gas species. The remote plasma may further generate photons, such as UV radiation, from the reducing gas species. For example, coils 544 may surround the walls of the remote plasma source 540 and generate a remote plasma in the remote plasma source 540.

In some embodiments, the coils 544 may be in electrical communication with a radio frequency (RF) power source or microwave power source. An example of a remote plasma source 540 with an RF power source can be found in the GAMMA®, manufactured by Lam Research Corporation of Fremont, Calif. Another example of an RF remote plasma source 540 can be found in the Astron®, manufactured by MKS Instruments of Wilmington, Mass., which can be operated at 440 kHz and can be provided as a subunit bolted onto a larger apparatus for processing one or more substrates in parallel. In some embodiments, a microwave plasma can be used with the remote plasma source 540, as found in the Astex®, also manufactured by MKS Instruments. A microwave plasma can be configured to operate at a frequency of 2.45 GHz.

In embodiments with an RF power source, the RF generator may be operated at any suitable power to form a plasma of a desired composition of radical species. Examples of suitable powers include, but are not limited to, powers between about 0.5 kW and about 6 kW. Likewise, the RF generator may provide RF power of a suitable frequency, such as 13.56 MHz for an inductively-coupled plasma.

Reducing gas species 520 are delivered from a gas inlet 542 and into an internal volume of the remote plasma source 540. The power supplied to the coils 544 can generate a remote plasma with the reducing gas species 520 to form radicals of the reducing gas species 520. The radicals formed in the remote plasma source 540 can be carried in the gas phase towards the substrate 510 through the showerhead 530. An example of a remote plasma source 540 with such a configuration can be described in U.S. Pat. No. 7,074,339 (attorney docket no. NOVLP414), issued Dec. 27, 2011, which is incorporated herein by reference in its entirety and for all purposes. The radicals of the reducing gas species 520 can reduce metal oxides on the surface of the substrate 510.

In addition to radicals of the reducing gas species, the remote plasma can also generate and include ions and other charged species of the reducing gas species 520. In some embodiments, the remote plasma may include neutral molecules of the reducing gas species 520. Some of the neutral molecules may be recombined molecules of charged species from the reducing gas species 520. The neutrals or recombined molecules of the reducing gas species 520 can also reduce metal oxides on the surface of the substrate 510, though they may take longer to react and reduce the metal oxides than the radicals of the reducing gas species 520. The ions may drift to the surface of the substrate 510 and reduce the metal oxides, or the ions may be accelerated toward the surface of the substrate 510 to reduce the metal oxides if the substrate support 505 has an oppositely charged bias. Having species with higher ion energies can allow deeper implantation into the metal seed layer to create metastable radical species further from the surface of the substrate 510. For example, if the substrate 510 has high aspect ratio features, such as between about 10:1 and about 60:1, ions with higher ionic energies may penetrate deeper into such features to provide reduction of the metal oxide more throughout the features. In contrast, some of the radicals of the reducing gas species 520 from remote plasma generation may recombine in the field or near the top of the features. The ions with higher ionic energies (such as 10 eV-100 eV) can also be used to re-sputter and reflow the metal in the metal seed layer, which can result in a more uniform seed coverage and reduce the aspect ratio for subsequent plating or metal deposition (such as PVD, CVD, ALD).

In FIG. 5, the remote plasma apparatus 500 may actively cool or otherwise control the temperature of the substrate 510. In some embodiments, it may be desirable to control the temperature of the substrate 510 to control the rate of the reduction reaction and the uniformity of exposure to the remote plasma during processing. It may also be desirable to control the temperature of the substrate 510 to reduce the effects of oxidation on the substrate 510 before, during, and/or after processing.

In some embodiments, the remote plasma apparatus 500 can include movable members 515, such as lift pins, that are capable of moving the substrate 510 away from or towards the substrate support 505. The movable members 515 may contact the lower surface of the substrate 510 or otherwise pick up the substrate 510 from the substrate support 505. In some embodiments, the movable members 515 may move the substrate 510 vertically and control the spacing between the substrate 510 and the substrate support 505. In some embodiments, the movable members 515 can include two or more actuatable lift pins. The movable members 515 can be configured to extend between about 0 inches and about 5 inches, or more, away from the substrate support 505. The movable members 515 can extend the substrate 510 away from a hot substrate support 505 and towards a cool showerhead 530 to cool the substrate 510. The movable members 515 can also retract to bring the substrate 510 towards a hot substrate support 505 and away from a cool showerhead 530 to heat the substrate 510. By positioning the substrate 510 via the movable members 515, the temperature of the substrate 510 can be adjusted. When positioning the substrate 510, the showerhead 530 and the substrate support 505 can be held at a constant temperature.

In some embodiments, the remote plasma apparatus 500 can include a showerhead 530 that allows for control of the showerhead temperature. An example of a showerhead configuration that permits temperature control can be described in U.S. Pat. No. 7,137,467 (attorney docket no. NOVLP246), issued Mar. 20, 2012, and U.S. Patent Publication No. 2009/0095220 (attorney docket no. NOVLP246X1), published Apr. 16, 2009, both of which are incorporated herein by reference in their entirety and for all purposes. Another example of a showerhead configuration that permits temperature control can be described in U.S. Patent Publication No. 2011/0146571 (attorney docket no. NOVLP329), published Jun. 23, 2011, which is incorporated herein by reference in its entirety and for all purposes. To permit active cooling of the showerhead 530, a heat exchange fluid may be used, such as deionized water or a thermal transfer liquid manufactured by the Dow Chemical Company in Midland, Mich. In some embodiments, the heat exchange fluid may flow through fluid channels (not shown) in the showerhead 530. In addition, the showerhead 530 may use a heat exchanger system (not shown), such as a fluid heater/chiller to control temperature. In some embodiments, the temperature of the showerhead 530 may be controlled to below about 30° C., such as between about 5° C. and about 20° C. The showerhead 530 may be cooled to reduce damage to the metal seed layer that may result from excess heat during processing of the substrate 510. The showerhead 530 may also be cooled to lower the temperature of the substrate 510, such as before and after processing the substrate 510.

In some embodiments, the showerhead 530 may include a plurality of holes. Increasing the size and number of holes in the showerhead 530 and/or decreasing the thickness of the showerhead 530 may permit greater flow of radicals, ions, and UV radiation from the reducing gas species 520 through the showerhead 530. Exposing the metal seed layer to more radicals, ions, and UV radiation can provide more UV exposure and energetic species to reduce metal oxide in the metal seed layer. In some embodiments, the showerhead 530 can include between about 100 and about 900 holes. In some embodiments, an average diameter of the holes can be between about 0.05 and about 0.5 inches. This can result in an open area in the showerhead 530 due to holes of between about 3.7% and about 25%. In some embodiments, the showerhead 530 can have a thickness between about 0.25 and about 3.0 inches.

In some embodiments, the substrate support 505 may be configured to move to and away from the showerhead 530. The substrate support 505 may extend vertically to control the spacing between the substrate 510 and the showerhead 530. When reducing metal oxides on the substrate 510, the uniformity as well as the rate of the reduction on the substrate 510 may be tuned. For example, if the substrate support 505 is closer to the showerhead 530, reduction of the metal oxide on the surface of the substrate 510 may proceed faster. However, the center of the substrate 510 may get hotter than the edges of the substrate 510, which can result in a less uniform reduction treatment. Accordingly, the spacing between the substrate 510 and the showerhead 530 can be adjusted to obtain a desired rate and uniformity for processing the substrate 510. In some embodiments, the substrate support 505 can be configured to extend between about 0 inches and about 5 inches, or greater than about 5 inches, from the showerhead 530.

In some embodiments, the temperature of the substrate support 505 may also be adjusted. In some embodiments, the substrate support 505 can be a pedestal with one or more fluid channels (not shown). The fluid channels may circulate a heat transfer fluid within the pedestal to actively cool or actively heat the pedestal, depending on the temperature of the heat transfer fluid. Embodiments that include such fluid channels and heat transfer fluids can be described in actively cooled pedestal systems discussed earlier herein. The circulation of the heat transfer fluid through one or more fluid channels can control the temperature of the substrate support 505. Temperature control of the substrate support 505 can control the temperature of the substrate 510 to a finer degree. In some embodiments, the temperature of the substrate support 505 can be adjusted to be between about 0° C. and about 400° C.

In some embodiments, the remote plasma apparatus 500 can include one or more gas inlets 522 to flow cooling gas 560 through the processing chamber 550. The one or more gas inlets 522 may be positioned above, below, and/or to the side of the substrate 510. Some of the one or more gas inlets 522 may be configured to flow cooling gas 560 in a direction that is substantially perpendicular to the surface of the substrate 510. In some embodiments, at least one of the gas inlets 522 may deliver cooling gas 560 through the showerhead 530 to the substrate 510. Some of the one or more gas inlets 522 may be parallel to the plane of the substrate 510, and may be configured to deliver a cross-flow of cooling gas 560 across the surface of the substrate 510. In some embodiments, the one or more gas inlets 522 may deliver cooling gas 560 above and below the substrate 510. The flow of cooling gas 560 across the substrate 510 can enable rapid cooling of the substrate 510. Rapid cooling of the substrate 510 can reduce the oxidation of the metal seed layer in the substrate 510. Such cooling of the substrate 510 may take place before and after processing of the substrate 510. The flow rate of the cooling gas 560 for cooling can be between about 0.1 standard liters per minute (slm) and about 100 slm.

Examples of cooling gas 560 can include a relatively inert gas, such as nitrogen, helium, neon, krypton, xenon, radon, and argon. In some embodiments, the cooling gas 560 can include at least one of nitrogen, helium, and argon.

In some embodiments, the cooling gas 560 can be delivered at room temperature, such as between about 10° C. and about 30° C. In some embodiments, the cooling gas 560 can be delivered at a temperature less than room temperature. For example, a cold inert gas may be formed by expanding a cold liquid to gas, such as liquid argon, helium, or nitrogen. Thus, the temperature range of the cooling gas 560 used for cooling can be broadened to be anywhere between about −270° C. and about 30° C.

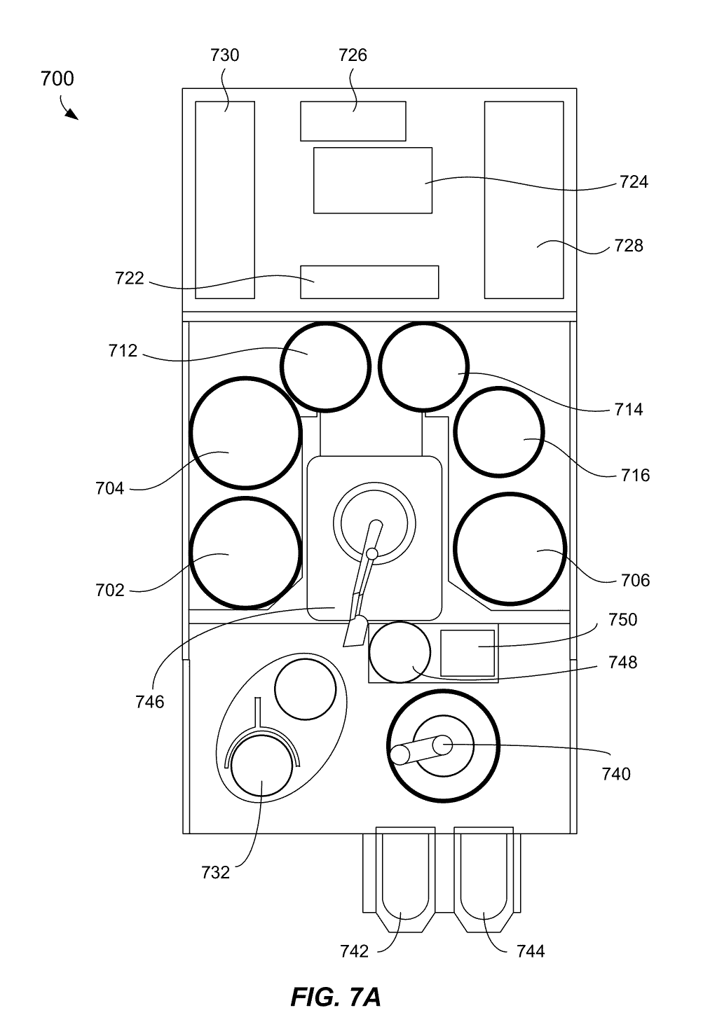

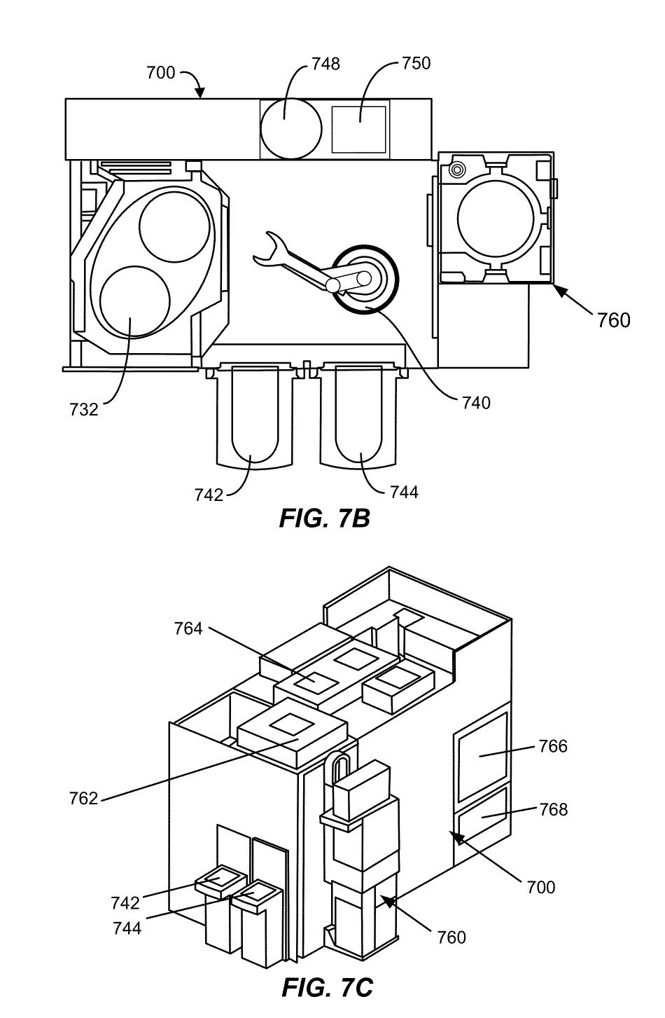

In some embodiments, the remote plasma apparatus 500 may be part of or integrated with an electroplating apparatus (not shown). This can be shown in FIGS. 7B and 7C, which is discussed in more detail below. Oxidation of the metal seed layer in the substrate 510 can occur rapidly during exposure to ambient conditions. By attaching or otherwise connecting the remote plasma apparatus 500 to the electroplating apparatus, the duration of exposure to ambient conditions of the substrate 510 can be reduced. For example, the transfer time between the remote plasma apparatus following treatment and the electroplating apparatus can be between about 15 seconds and about 90 seconds, or less than about 15 seconds.

Table I summarizes exemplary ranges of process parameters that can be used with certain embodiments of a remote plasma apparatus 500.

TABLE I

| Parameter | Parameter Range | |
|---|---|---|
| Pedestal Temperature | 0° C.-400° C. | |
| Showerhead Temperature | 5° C.-30° C. | |
| Pedestal Dropping Vertical Travel | 0″-5″ | |
| Lift Pins Raising Vertical Travel | 0″-5″ | |
| Cooling Gas Flow (N₂/Ar/He - | 0.1-100 | slm |
| pure or mixture) | | |
| Cooling Gas Temperature | −270° C.-30° C. | |
| Process Gas Flow (H₂/He/NH₃ - | 0.5 slm-30 slm | |
| pure or mixture) | | |
| Process Pressure | 0.5-6 | Torr |
| Venting Gas Flow | Nominally same as cooling gas | |
| Venting Gas | Nominally same as cooling gas | |
| RF Plasma Power | 0.5-6 | kW |
| Remote Plasma Apparatus to | 15-90 | seconds |
| Electroplating Apparatus | | |
| Transfer Time | | |

| | |
|---|---|
| Showerhead hole number | 100-900 |
| Showerhead thickness | 0.25″-3.0″ |
| Showerhead hole diameter | 0.05″-0.5″ |
| Showerhead open area due to holes | 3.7%-25% |

A controller 535 may contain instructions for controlling parameters for the operation of the remote plasma apparatus 500. The controller 535 will typically include one or more memory devices and one or more processors. The processor may include a CPU or computer, analog and/or digital input/output connections, stepper motor controller boards, etc. Aspects of the controller 535 may be further described with respect to the controller in FIGS. 7A and 7B. Various stages of treating a substrate with a metal seed layer using a remote plasma apparatus can be applied to a substrate with a semi-noble metal layer, which can be described in U.S. patent application Ser. No. 14/020,339 (attorney docket no. LAMRP061), filed Sep. 6, 2013, and U.S. patent application Ser. No. 14/076,770 (attorney docket no. LAMRP061X1), filed Nov. 21, 2013, both of which are incorporated herein by reference in their entirety and for all purposes.

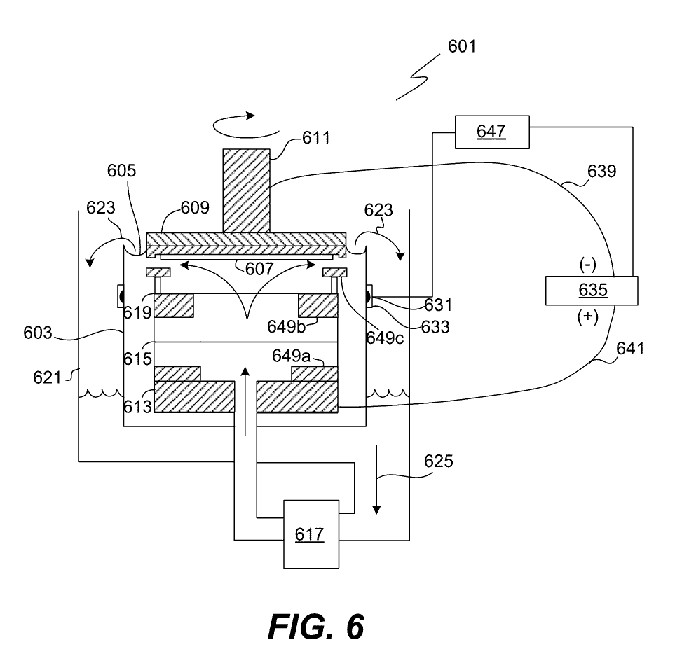

Referring to FIG. 6, a cross-sectional schematic view of an electroplating apparatus 601 is shown. The plating vessel 603 contains the plating solution, which is shown at a level 605. A substrate 607 is immersed into the plating solution and is held by, e.g., a “clamshell” holding fixture 609, mounted on a rotatable spindle 611, which allows rotation of clamshell 609 together with the substrate 607. A general description of a clamshell-type plating apparatus having aspects suitable for use with this embodiment can be described in detail in U.S. Pat. No. 6,156,167 issued to Patton et al., and U.S. Pat. No. 6,700,177 (attorney docket no. NOVLP020) issued to Reid et al., both of which are incorporated herein by reference for all purposes. An anode 613 is disposed below the substrate 607 within the plating bath 603 and is separated from the substrate region by a membrane 615, preferably an ion selective membrane. The region below the anodic membrane is often referred to as an “anode chamber.” The ion-selective anode membrane 615 allows ionic communication between the anodic and cathodic regions of the plating cell, while preventing the particles generated at the anode from entering the proximity of the substrate 607 and contaminating it. The anode membrane 615 is also useful in redistributing current flow during the plating process and thereby improving the plating uniformity. Detailed descriptions of suitable anodic membranes can be provided in U.S. Pat. No. 6,126,797 and U.S. Pat. No. 6,569,299 issued to Reid et al., both of which are incorporated herein by reference in their entirety and for all purposes.

The plating solution is continuously provided to plating bath 603 by a pump 617. Generally, the plating solution flows upwards through an anode membrane 615 and a diffuser plate 619 to the center of substrate 607 and then radially outward and across substrate 607. The plating solution also may be provided into anodic region of the bath from the side of the plating cell 603. The plating solution then overflows plating bath 603 to an overflow reservoir 621 as indicated by arrows 623. The plating solution is then filtered (not shown) and returned to pump 617 as indicated by arrow 625 completing the recirculation of the plating solution. In certain configurations of the plating cell, a distinct electrolyte is circulated through the portion of the plating cell in which the anode is contained and mixing with the main plating solution is prevented using sparingly permeable membranes or ion selective membranes.

A reference electrode 631 is located on the outside of the plating vessel 603 in a separate chamber 633, which chamber is replenished by overflow from the main plating vessel. A reference electrode is typically employed when electroplating at a controlled potential is desired. The reference electrode 631 may be one of a variety of commonly used types such as mercury/mercury sulfate, silver chloride, saturated calomel, or copper metal. In the context of this disclosure, voltages applied to the substrate 607 are expressed relative to the copper metal reference electrode.

A DC power supply 635 can be used to control current flow to the substrate 607. The power supply 635 has a negative output lead 639 electrically connected to substrate 607 through one or more slip rings, brushes and contacts (not shown). The positive output lead 641 of power supply 635 is electrically connected to an anode 613 located in plating bath 603. The power supply 635 and a reference electrode 631 can be connected to a controller 647, which allows modulation of current and potential provided to the elements of electroplating cell. For example, the controller may allow electroplating either in galvanostatic (controlled current) or potentiostatic (controlled potential) regime. The controller may include program instructions specifying current and voltage levels that need to be applied to various elements of the plating cell, as well as times at which these levels need to be changed. For example, it may include program instructions for transitioning from forward current (depositing copper) to reverse current (removing copper) or from potential-control to current-control upon complete immersion of the substrate 607 into the plating bath 603 or at some later time.

During a forward current pulse, the power supply 635 biases the substrate 607 to have a negative potential relative to anode 613. This causes an electrical current to flow from anode 613 to the substrate 607, and an electrochemical reduction (e.g., Cu²⁺+2e⁻=Cu⁰) occurs on the substrate surface (the cathode), which results in the deposition of the electrically conductive layer (e.g. copper) on the surfaces of the substrate 607. During a reverse current pulse, the opposite is true. The reaction on the substrate surface is an oxidation (e.g., Cu⁰-->Cu²⁺+2e⁻), which results in the removal of the copper.

An electroplating operation (e.g., electroplating a copper seed layer) of the process can occur using the electroplating apparatus 601. Further details of a two-step cooper electroplating process may be found in U.S. patent application Ser. No. 11/672,175 (attorney docket no. NOVLP207), filed on Mar. 5, 2007, the disclosure of which is hereby incorporated by reference in its entirety for all purposes.

FIG. 7A shows an example of a top view schematic of an electroplating apparatus. The electroplating apparatus 700 can include three separate electroplating modules 702, 704, and 706. The electroplating apparatus 700 can also include three separate modules 712, 714, and 716 configured for various process operations. For example, in some embodiments, modules 712 and 716 may be spin rinse drying (SRD) modules and module 714 may be an annealing station. However, the use of SRD modules may be rendered unnecessary after exposure to a reducing gas species from a remote plasma treatment. In some embodiments, at least one of the modules 712, 714, and 716 may be post-electrofill modules (PEMs), each configured to perform a function, such as edge bevel removal, backside etching, acid cleaning, spinning, and drying of substrates after they have been processed by one of the electroplating modules 702, 704, and 706.

The electroplating apparatus 700 can include a central electroplating chamber 724. The central electroplating chamber 724 is a chamber that holds the chemical solution used as the plating solution in the electroplating modules 702, 704, and 706. The electroplating apparatus 700 also includes a dosing system 726 that may store and deliver additives for the plating solution. A chemical dilution module 722 may store and mix chemicals that may be used as an etchant. A filtration and pumping unit 727 may filter the plating solution for the central electroplating chamber 724 and pump it to the electroplating modules 702, 704, and 706.

In some embodiments, an annealing station 732 may be used to anneal substrates as pretreatment. The annealing station 732 may include a number of stacked annealing devices, e.g., five stacked annealing devices. The annealing devices may be arranged in the annealing station 732 one on top of another, in separate stacks, or in other multiple device configurations.

A system controller 730 provides electronic and interface controls required to operate the electroplating apparatus 700. The system controller 730 (which may include one or more physical or logical controllers) controls some or all of the properties of the electroplating apparatus 700. The system controller 730 typically includes one or more memory devices and one or more processors. The processor may include a central processing unit (CPU) or computer, analog and/or digital input/output connections, stepper motor controller boards, and other like components. Instructions for implementing appropriate control operations as described herein may be executed on the processor. These instructions may be stored on the memory devices associated with the system controller 730 or they may be provided over a network. In certain embodiments, the system controller 730 executes system control software.

The system control software in the electroplating apparatus 700 may include electroplating instructions for controlling the timing, mixture of the electrolyte components, inlet pressure, plating cell pressure, plating cell temperature, substrate temperature, current and potential applied to the substrate and any other electrodes, substrate position, substrate rotation, and other parameters performed by the electroplating apparatus 700. System control software may be configured in any suitable way. For example, various process tool component sub-routines or control objects may be written to control operation of the process tool components necessary to carry out various process tool processes. System control software may be coded in any suitable computer readable programming language.

In some embodiments, system control software includes input/output control (IOC) sequencing instructions for controlling the various parameters described above. For example, each phase of an electroplating process may include one or more instructions for execution by the system controller 730, and each phase of the pretreatment or reducing process may include one or more instructions for execution by the system controller 730. In electroplating, the instructions for setting process conditions for an immersion process phase may be included in a corresponding immersion recipe phase. In pretreatment or reducing, the instructions for setting process conditions for exposing the substrate to a remote plasma may be included in a corresponding reducing phase recipe. In some embodiments, the phases of electroplating and reducing processes may be sequentially arranged, so that all instructions for a process phase are executed concurrently with that process phase.

Other computer software and/or programs may be employed in some embodiments. Examples of programs or sections of programs for this purpose include a substrate positioning program, an electrolyte composition control program, a pressure control program, a heater control program, a potential/current power supply control program. Other examples of programs or sections of this program for this purpose include a timing control program, movable members positioning program, a substrate support positioning program, a remote plasma apparatus control program, a pressure control program, a substrate support temperature control program, a showerhead temperature control program, a cooling gas control program, and a gas atmosphere control program.

In some embodiments, there may be a user interface associated with the system controller 730. The user interface may include a display screen, graphical software displays of the apparatus and/or process conditions, and user input devices such as pointing devices, keyboards, touch screens, microphones, etc.

Signals for monitoring the process may be provided by analog and/or digital input connections of the system controller 730 from various process tool sensors. The signals for controlling the process may be output on the analog and digital output connections of the process tool. Non-limiting examples of process tool sensors that may be monitored include mass flow controllers, pressure sensors (such as manometers), thermocouples, etc. Appropriately programmed feedback and control algorithms may be used with data from these sensors to maintain process conditions, such as temperature of the substrate.

A hand-off tool 740 may select a substrate from a substrate cassette such as the cassette 742 or the cassette 744. The cassettes 742 or 744 may be front opening unified pods (FOUPs). A FOUP is an enclosure designed to hold substrates securely and safely in a controlled environment and to allow the substrates to be removed for processing or measurement by tools equipped with appropriate load ports and robotic handling systems. The hand-off tool 740 may hold the substrate using a vacuum attachment or some other attaching mechanism.

The hand-off tool 740 may interface with the annealing station 732, the cassettes 742 or 744, a transfer station 750, or an aligner 748. From the transfer station 750, a hand-off tool 746 may gain access to the substrate. The transfer station 750 may be a slot or a position from and to which hand-off tools 740 and 746 may pass substrates without going through the aligner 748. In some embodiments, however, to ensure that a substrate is properly aligned on the hand-off tool 746 for precision delivery to an electroplating module, the hand-off tool 746 may align the substrate with an aligner 748. The aligner 748 can include alignment pins against which the hand-off tool 740 pushes the substrate. When the substrate is properly aligned against the alignment pins, the hand-off tool 740 moves to a preset position with respect to the alignment pins. The hand-off tool 746 may also deliver a substrate to one of the electroplating modules 702, 704, or 706 or to one of the three separate modules 712, 714, and 716 configured for various process operations.

The copper seed layer may be electroplated onto the substrate in one of the electroplating modules 702, 704, and 706. After the seed layer electroplating operation completes, the hand-off tool 740 may remove the substrate from one of the electroplating modules 702, 704, and 706, and may transport the substrate to one of the PEMs 712, 714, and 716. For example, one of the PEMs 712, 714, and 716 may clean, rinse, and dry the substrate. The substrate can then be picked up with the hand-off tool 740 and placed in the transfer station 750. The transfer station 750 may be a slot or a position from and to which hand-off tool 740 and 746 may pass substrates without going through the aligner 748. The hand-off tool 740 then moves the substrate from the transfer chamber 750, optionally to the cassette, or to one of the anneal stations or remote plasma apparatus. If the substrate is inserted into the cassette, it may be stored for treatment and bulk electroplating at a later time. Alternatively, it may be simply moved to the anneal station or remote plasma apparatus. Afterwards, the hand-off tool 740 can move the substrate back through the aligner 748 and the hand-off tool 746 to one of the electroplating modules 702, 704, and 706 for bulk electroplating. After the features are filled with copper, the substrate can be moved to one of the PEMs 712, 714, and 716. In some instances, unwanted copper from certain locations on the substrate (namely the edge bevel region and the backside) can be etched away by an etchant solution provided by chemical dilution module 722. The PEMs 712, 714, and 716 can also clean, rinse, and dry the substrate.

In some embodiments, a remote plasma apparatus may be part of or integrated with the electroplating apparatus 700. FIG. 7B shows an example of a magnified top view schematic of a remote plasma apparatus with an electroplating apparatus. However, it is understood by those of ordinary skill in the art that the remote plasma apparatus may alternatively be attached to an electroless plating apparatus or other metal deposition apparatus. FIG. 7C shows an example of a three-dimensional perspective view of a remote plasma apparatus attached to an electroplating apparatus. The remote plasma apparatus 760 may be attached to the side of the electroplating apparatus 700. The remote plasma apparatus 760 may be connected to the electroplating apparatus 700 in such a way so as to facilitate efficient transfer of the substrate to and from the remote plasma apparatus 760 and the electroplating apparatus 700. The hand-off 740 may gain access to the substrate from cassette 742 or 744. The hand-off tool 740 may pass the substrate to the remote plasma apparatus 760 for exposing the substrate to a remote plasma treatment and a cooling operation. The hand-off tool 740 may pass the substrate from the remote plasma apparatus 760 to the transfer station 750. In some embodiments, the aligner 748 may align the substrate prior to transfer to one of the electroplating modules 702, 704, and 706 or one of the three separate modules 712, 714, and 716.

Operations performed in the electroplating apparatus 700 may introduce exhaust that can flow through front-end exhaust 762 or a back-end exhaust 764. The electroplating apparatus 700 may also include a bath filter assembly 766 for the central electroplating station 724, and a bath and cell pumping unit 767 for the electroplating modules 702, 704, and 706.

In some embodiments, the system controller 730 may control the parameters for the process conditions in the remote plasma apparatus 760. Non-limiting examples of such parameters include substrate support temperature, showerhead temperature, substrate support position, movable members position, cooling gas flow, cooling gas temperature, process gas flow, process gas pressure, venting gas flow, venting gas, reducing gas, plasma power, and exposure time, transfer time, etc. These parameters may be provided in the form of a recipe, which may be entered utilizing the user interface as described earlier herein.

Operations in the remote plasma apparatus 760 that is part of the electroplating apparatus 700 may be controlled by a computer system. In some embodiments, the computer system is part of the system controller 730 as illustrated in FIG. 7A. In some embodiments, the computer system may include a separate system controller (not shown) including program instructions. The program instructions may include instructions to perform all of the operations needed to reduce metal oxides to metal in a semi-noble metal layer or metal seed layer. The program instructions may also include instructions to perform all of the operations needed to cool the substrate, position the substrate, and load/unload the substrate.

In some embodiments, a system controller may be connected to a remote plasma apparatus 760 in a manner as illustrated in FIG. 5. In one embodiment, the system controller includes instructions for providing a substrate with a semi-noble metal layer formed thereon in a processing chamber, forming a remote plasma of a reducing gas species in a remote plasma source, where the remote plasma includes radicals of the reducing gas species, and exposing the semi-noble metal layer of the substrate to the remote plasma. In some embodiments, the system controller can include instructions for exposing the substrate to a cooling gas. The remote plasma may include one or more of radicals, ions, neutrals, and UV radiation from the reducing gas species, resulting in the semi-noble metal layer being exposed to one or more of radicals, ions, neutrals, and UV radiation from the reducing gas species. The system controller may further include instructions for performing operations as described earlier herein with respect to FIGS. 2, 3, 5, and 6.

The apparatus/process described hereinabove may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above-described processes may be changed.

### Examples and Data

FIG. 8 shows an example of an overview for a process flow for a plate on liner sequence. The plating solutions and the pretreatment processes described earlier herein may be applied with respect to the process flow shown in FIG. 8. In FIG. 8, a substrate can have features such as trenches and vias etched therein for depositing a liner and/or barrier layer. The features can have a height to width aspect ratio of greater than about 5:1, such as greater than about 10:1. The substrate can include a barrier layer of tantalum upon which a cobalt liner may be deposited thereon. The cobalt liner may be deposited using an appropriate deposition technique, such as CVD or ALD. The cobalt liner may provide a layer of relatively low resistivity. Copper seed may be deposited over the cobalt liner using a plating solution having either at least two copper complexing agents having different multidentate ligands or a single hexadentate copper complexing agent having a concentration of at least twice more than a copper source. Prior to depositing the copper seed, the cobalt liner may be pretreated using a dry pretreatment process to remove cobalt oxides. A bulk layer of copper may substantially fill the features in the substrate by electroplating.

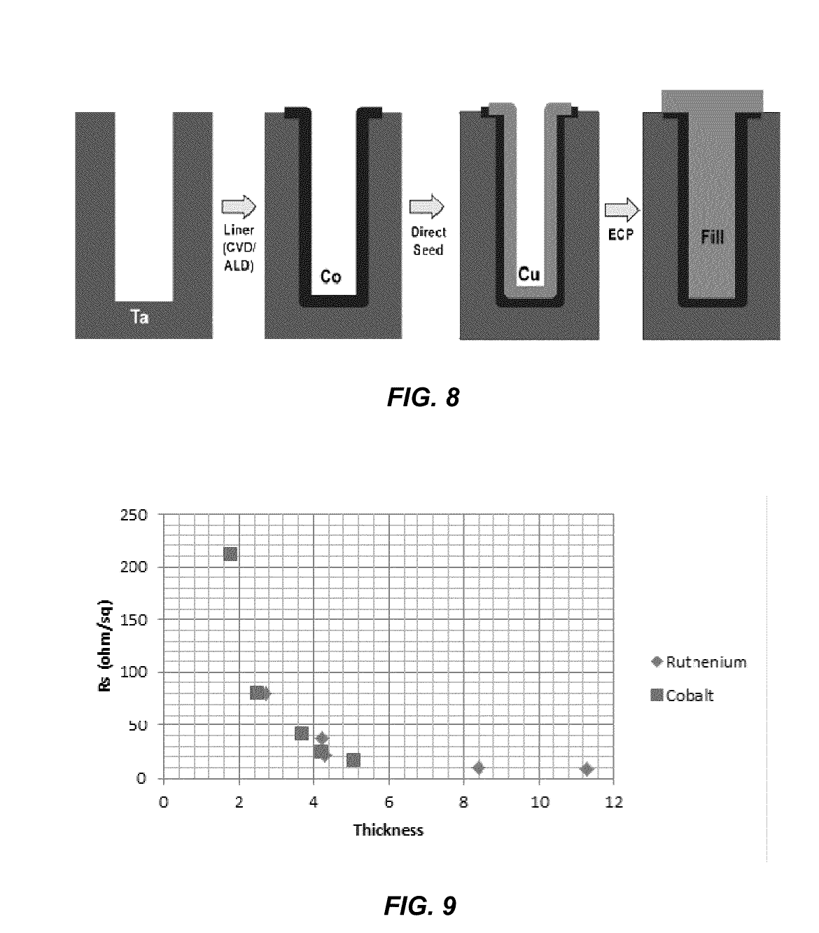

FIG. 9 shows a comparison between minimal continuous plated copper seed thickness for a plate on cobalt and a plate on ruthenium process. The plot was obtained by graphing the measured transmission electron microscopy (TEM) thickness of the plated copper seed versus the sheet resistance via four point probe measurements. The minimum continuous thickness is obtained by extrapolating the slope line of the sharp increase in sheet resistance down to the thickness scale. The minimum continuous thickness of plated copper calculated via the method described above is between about 3.2 nm and about 4.0 nm, which is similar for both plate on cobalt and plate on ruthenium processes.

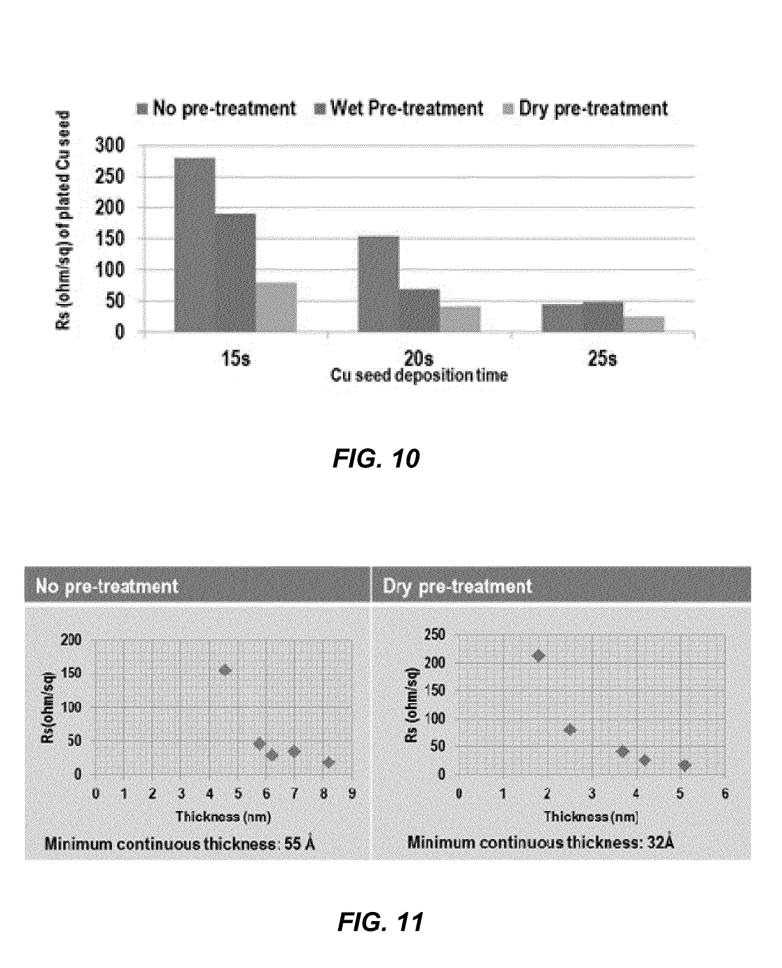

FIG. 10 shows a comparison between sheet resistance values of plated copper seed at various deposition times on control, wet pretreated, and dry pretreated samples. The dry pretreatment exposed the cobalt film to a remote plasma at 250° C. and the wet pretreatment exposed the cobalt film to a NH₃BH₃ chemical solution. The copper seed layer having its underlying cobalt film exposed to a dry pretreatment resulted in a significantly more conductive copper seed layer. The longer deposition times also resulted in a more conductive copper seed layer. Without being limited by any theory, the remote plasma pretreatment can increase the conductivity of the copper seed layer by removing organic impurities left behind from precursors of the cobalt film.

FIG. 11 shows a comparison between sheet resistance values and minimal continuous plated copper seed thickness on control and dry pretreated samples. The minimum continuous seed thicknesses for the dry pretreated samples were smaller than the continuous seed thicknesses for the untreated samples.

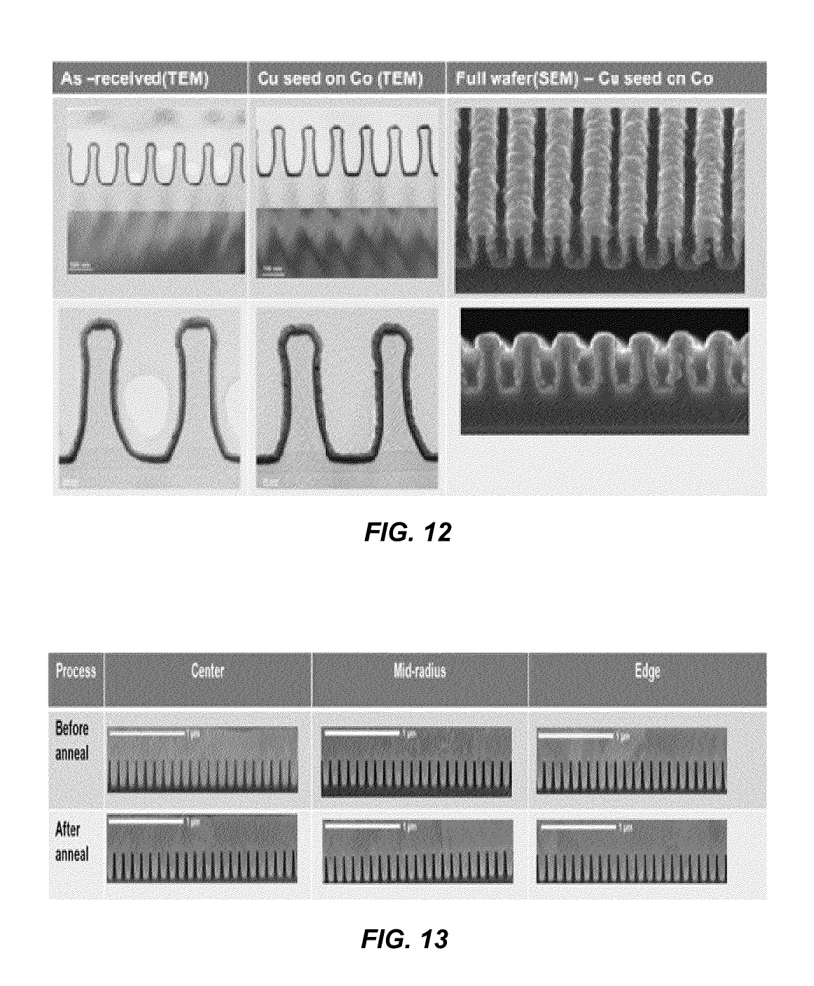

FIG. 12 shows transmission electron microscopy (TEM) and scanning electron microscopy (SEM) images of bare cobalt as well as copper seed on a cobalt wafer plated with a dual complex alkaline bath. SEM images show continuous coverage of Cu seed in the Co features. A copper seed film can be deposited on a cobalt layer formed on a substrate with the 90 nm features. The TEM images the as-received features with bare cobalt and copper seed coverage on cobalt using an EDTA-bipyridine-Cu plating solution.

FIG. 13 shows images of copper fill before and after anneal on copper seed plated on a cobalt wafer with a dual complex alkaline bath. Void free fill after thermal anneal shows robustness of the interface between copper and cobalt and excellent adhesion.

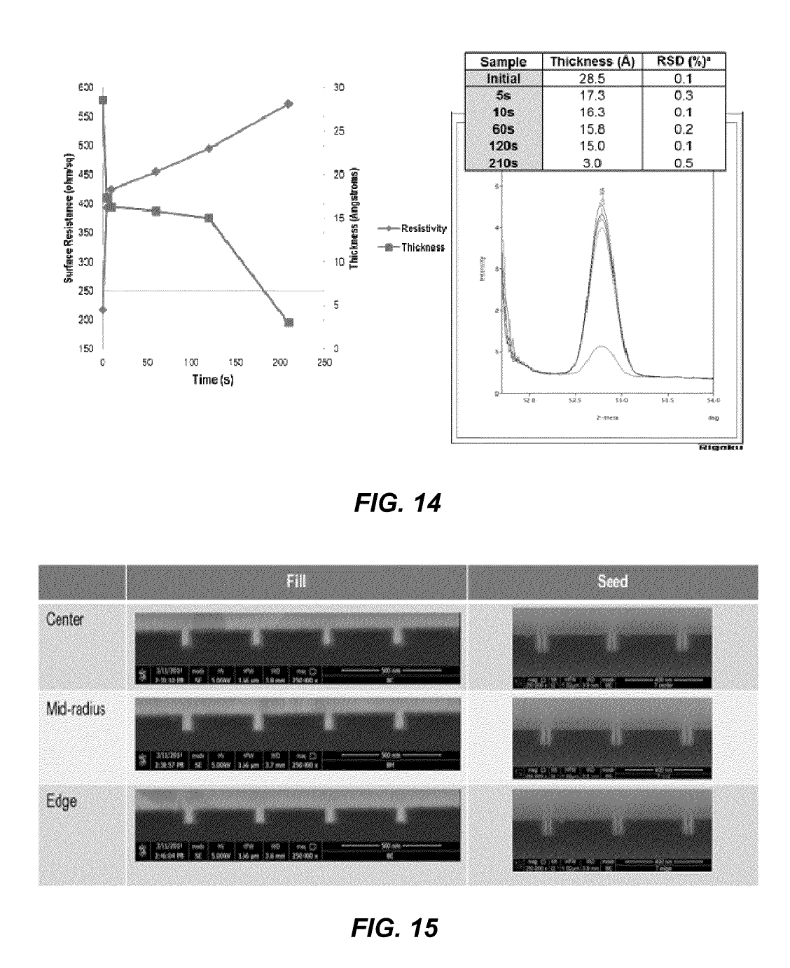

FIG. 14 shows a graph illustrating cobalt etching in terms of sheet resistance values and thickness in acidic plating conditions and a corresponding x-ray fluorescence (XRF) for a cobalt dissolution rate. In acidic plating conditions, a layer of cobalt etches rapidly in the first 10 seconds and slows down afterwards. Approximately 1.2 nm of cobalt dissolves within 10 seconds and then etches slowly thereafter (about 0.5 Å/min). Then after 2 minutes, the cobalt rapidly dissolves until it is all gone.

FIG. 15 shows SEM images of copper fill and copper seed plated on a cobalt wafer with a hexadentate complex acidic bath.

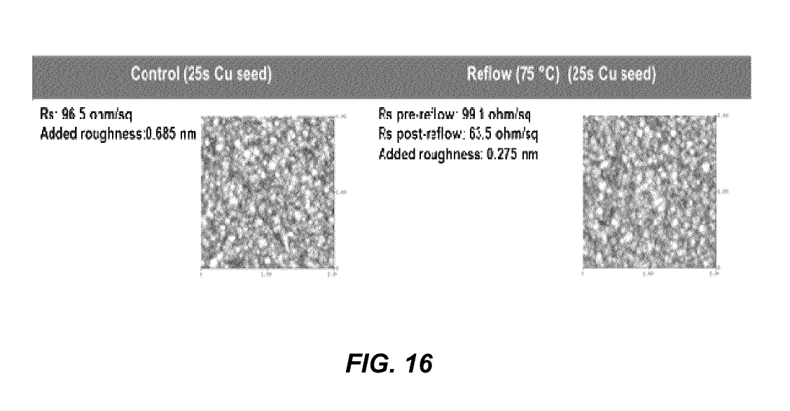

FIG. 16 shows images that demonstrate the effect of reflow on copper sheet resistance and roughness. Reflowing the copper seed layer can reduce the sheet resistance and surface roughness of the copper seed layer. Without performing a reflow, the copper seed had a sheet resistance of 96.5 ohm/square and an additional surface roughness of about 0.685 nm. On the other hand, copper seed improved its sheet resistance from 99.1 ohm/square before reflow to 63.5 ohm/square after reflow while having an additional surface roughness of about 0.275 nm.

### Other Embodiments

Although the foregoing has been described in some detail for purposes of clarity and understanding, it will be apparent that certain changes and modifications may be practiced within the scope of the appended claims. It should be noted that there are many alternative ways of implementing the processes, systems, and apparatus described. Accordingly, the described embodiments are to be considered as illustrative and not restrictive.

What is claimed is:

1. A method of preparing a substrate with a semi-noble metal layer for plating copper on the substrate, the method comprising:
providing a substrate with a semi-noble metal layer formed thereon in a processing chamber;
exposing the semi-noble metal layer to a reducing treatment under conditions that reduce an oxide of the metal to a metal in the form of a film integrated with the semi-noble metal layer; and
depositing a copper seed layer on the semi-noble metal layer using a plating bath with a plating solution, wherein the plating solution includes a copper source and either at least two copper complexing agents having at least two different polydentate ligands or a single hexadentate copper complexing agent, wherein the single hexadentate copper complexing agent has a concentration at least twice that of the copper source.

2. The method of claim 1, wherein at least one of the polydentate ligands is ethylenediaminetetraacetic acid (EDTA).

3. The method of claim 1, wherein at least one of the polydentate ligands is 2, 2′-bipyridine.

4. The method of claim 1, wherein the semi-noble metal layer includes cobalt.

5. The method of claim 1, wherein exposing the semi-noble metal layer to a reducing treatment comprises:
forming a remote plasma of a reducing gas species in a remote plasma source, wherein the remote plasma comprises one or more of: radicals, ions, and ultraviolet (UV) radiation from the reducing gas species; and
exposing the semi-noble metal layer to the remote plasma.

6. The method of claim 5, wherein the reducing gas species includes hydrogen.

7. The method of claim 5, further comprising:
exposing the substrate to a cooling gas after exposing the semi-noble metal layer to the remote plasma.

8. The method of claim 1, wherein exposing the semi-noble metal layer includes contacting at least the oxide of the metal with a solution including a reducing agent.

9. The method of claim 1, further comprising:
after exposing at least the semi-noble metal layer to a reducing treatment, transferring the substrate to the plating bath containing the plating solution.

10. The method of claim 1, further comprising:
heating a substrate support holding the substrate to a processing temperature between about 0° C. and about 400° C.

11. The method of claim 1 wherein a thickness of the copper seed layer is between about 40 Å and about 80 Å.

12. The method of claim 1 wherein a plating surface of the substrate includes vias having a height to width aspect ratio of greater than about 5:1.

13. The method of claim 1, wherein the plating solution has a pH between about 3.0 and about 13.5.

14. The method of claim 1, wherein a portion of the semi-noble metal layer has been converted to an oxide of the metal.

15. The method of claim 1, further comprising:
depositing a bulk layer of copper on the copper seed layer using a plating bath different than the plating bath for the deposition of the copper seed layer.

16. The method of claim 15, further comprising:
reflowing the copper seed layer before depositing the bulk layer of copper, wherein the plating bath for the deposition of the copper seed layer is an alkaline bath and the plating bath for the deposition of the bulk layer of copper is an acidic bath.

17. An apparatus for preparing a substrate with a semi-noble metal layer, the apparatus comprising:
a processing chamber;
a substrate support for holding the substrate in the processing chamber;
a controller configured to provide instructions for performing the following operations:
(a) providing a substrate in a processing chamber;
(b) exposing the substrate to a reducing treatment under conditions that reduce an oxide of a metal to a metal in the form of a film integrated with a semi-noble metal layer disposed on the substrate; and
(c) depositing a copper seed layer on the semi-noble metal layer using a plating bath with a plating solution, wherein the plating solution includes a copper source and either at least two copper complexing agents having at least two different polydentate ligands or a single hexadentate copper complexing agent, wherein the single hexadentate copper complexing agent has a concentration at least twice that of the copper source.

18. The apparatus of claim of claim 17, wherein at least one of the polydentate ligands is ethylenediaminetetraacetic acid (EDTA).

19. The apparatus of claim 17, wherein at least one of the polydentate ligands is 2,2′-bipyridine.

20. The apparatus of claim 17, wherein the semi-noble metal layer includes cobalt.

21. The apparatus of claim 17, wherein exposing the semi-noble metal layer to a reducing treatment comprises:
forming a remote plasma of a reducing gas species in a remote plasma source, wherein the remote plasma comprises one or more of: radicals, ions, and ultraviolet (UV radiation from the reducing gas species; and
exposing the semi-noble metal layer to the remote plasma.

22. The apparatus of claim 21, wherein the reducing gas species includes hydrogen.

23. The apparatus of claim 17, wherein the plating solution has a pH between about 3.0 and about 13.5.

24. The apparatus of claim 17, wherein the controller is configured to farther perform:
depositing a bulk layer of copper on the copper seed layer using a plating bath different than the plating bath for the deposition of the copper seed layer.

25. The apparatus of claim 24, wherein the controller is configured to further perform:
reflowing the copper seed layer before depositing the bulk layer of copper, wherein the plating bath for the deposition of the copper seed layer is an alkaline bath and the plating bath for the deposition of the bulk layer of copper is an acidic bath.
